(19) United States
(12) Patent Application Publication
(10) Pub. No.: US 2025/0301782 A1
(43) Pub. Date: Sep. 25, 2025

(54) SEMICONDUCTOR DEVICE INCLUDING A FIELD EFFECT TRANSISTOR

(71) Applicant: SAMSUNG ELECTRONICS CO., LTD., SUWON-SI (KR)

(72) Inventor: MYOUNG-SUN LEE, Suwon-si (KR)

(21) Appl. No.: 19/010,607

(22) Filed: Jan. 6, 2025

(30) Foreign Application Priority Data
Mar. 22, 2024 (KR) 10-2024-0039864

(51) Int. Cl. H10D 84/85; H10D 84/01

(52) U.S. Cl. CPC H10D 84/851; H10D 84/0167; H10D 84/017; H10D 84/0186

(57) ABSTRACT

A semiconductor device includes a plurality of power lines disposed on a substrate. The power lines are arranged in a first direction and extended in a second direction and run parallel to each other. A first single height cell and a second single height cell are arranged in the first direction on the substrate. A first tap cell and a second tap cell are arranged in the first direction on the substrate. A power delivery network layer is disposed below the substrate. A first active pattern and a second active pattern are disposed between the power lines to be spaced apart from each other in the first direction. A first width of the first active pattern on the first single height cell is larger than or equal to a second width of the first active pattern on the first tap cell, when measured in the first direction.

### CROSS-REFERENCE TO RELATED APPLICATIONS

This U.S. non-provisional patent application claims priority under 35 U.S.C. § 119 to Korean Patent Application No. 10-2024-0039864, filed on Mar. 22, 2024, in the Korean Intellectual Property Office, the entire contents of which are hereby incorporated by reference.

### TECHNICAL FIELD

The present disclosure relates to a semiconductor device, and in particular, to a semiconductor device including a field effect transistor.

### DISCUSSION OF THE RELATED ART

Semiconductor devices may include an integrated circuit consisting of metal-oxide-semiconductor field-effect transistors (MOS-FETs). These MOS-FETs are being made smaller to satisfy industry demands. However, as MOS-FETs are scaled-down in size, the operational properties of the semiconductor device that includes the scaled-down MOS-FET may deteriorate. A variety of studies are being conducted to overcome technical limitations associated with the scale-down of the semiconductor device and to realize high-performance semiconductor devices.

### SUMMARY

A semiconductor device includes a plurality of power lines disposed on a substrate, the power lines are arranged in a first direction and extended in a second direction. A first single height cell and a second single height cell are arranged in the first direction on the substrate. A first tap cell and a second tap cell are arranged in the first direction on the substrate. The first tap cell and the first single height cell are arranged in the second direction. The second tap cell and the second single height cell are arranged in the second direction. A power delivery network layer is disposed below the substrate. A first active pattern and a second active pattern are disposed between the power lines and are spaced apart from each other in the first direction. The first and second active patterns are extended in the second direction and cross the first single height cell and the first tap cell. A first width of the first active pattern on the first single height cell is larger than or equal to a second width of the first active pattern on the first tap cell, in the first direction.

A semiconductor device includes first active patterns disposed on a substrate and adjacent to each other. First source/drain patterns are disposed on the first active patterns, respectively, and are adjacent to each other. A first division structure, a second division structure, and a third division structure cross the first active patterns. The first source/drain patterns are respectively interposed between the first and second division structures and between the second and third division structures. A penetration via pattern is disposed between the first source/drain patterns. A first power line is disposed on the penetration via pattern and is electrically connected to the penetration via pattern. A power delivery network layer is disposed on a bottom surface of the substrate. A lower via pattern is disposed between the power delivery network layer and the penetration via pattern. A bottom surface of the penetration via pattern is located at a level that is lower than that of a bottom surface of each of the first to third division structures.

A semiconductor device includes a first power line and a second power line disposed on a substrate. The first and second power lines are spaced apart from each other in a first direction and are extended in a second direction. A single height cell and a tap cell are disposed between the first and second power lines. The single height cell and the tap cell are adjacent to each other in the second direction. A first active pattern and a second active pattern are disposed on the single height cell and the tap cell. The first and second active patterns are spaced apart from each other in the first direction and are extended in the second direction. A first channel pattern and a first source/drain pattern are disposed on the first active pattern. A second channel pattern and a second source/drain pattern are disposed on the second active pattern. The second source/drain pattern has a conductivity type that is different from that of the first source/drain pattern. A gate electrode is disposed on the first and second channel patterns. A gate insulating layer is interposed between the gate electrode and the first and second channel patterns. A gate spacer is disposed on a side surface of the gate electrode. A gate capping pattern is disposed on a top surface of the gate electrode. An interlayer insulating layer covers the first and second source/drain patterns and the gate capping pattern. An active contact penetrates the interlayer insulating layer and is electrically connected to each of the first and second source/drain patterns. A metal-semiconductor compound layer is interposed between the active contact and each of the first and second source/drain patterns. A gate contact penetrates the interlayer insulating layer and the gate capping pattern and is electrically connected to the gate electrode. A first division structure, a second division structure, and a third division structure are arranged in the second direction. The first and third division structures are respectively disposed on opposite borders of the tap cell. A first penetration via pattern and a second penetration via pattern are disposed on the tap cell. The first and second penetration via patterns are electrically connected to the first and second power lines, respectively, and each of the first and second penetration via patterns is interposed between the first and third division structures. A power delivery network layer is disposed on a bottom surface of the substrate. A first lower via pattern and a second lower via pattern are disposed between the power delivery network layer and the first and second penetration via patterns, respectively. The largest width of each of the first and second lower via patterns in the second direction is larger than the largest width of each of the first and second penetration via patterns in the second direction.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIGS. 1 to 3 are conceptual diagrams illustrating logic cells in a semiconductor device according to an embodiment of the inventive concept;

FIG. 4 is a plan view illustrating a semiconductor device according to an embodiment of the inventive concept;

FIGS. 5A to 5F are cross-sectional views taken along lines A-A′, B-B′, C-C′, D-D′, E-E′, and F-F′ of FIG. 4, respectively;

FIG. 6 is an enlarged plan view illustrating a portion of FIG. 4;

FIGS. 7A and 7B are enlarged plan views illustrating examples of the portion shown in FIG. 6;

FIGS. 8A and 8B are a plan views illustrating an arrangement of tap cells and logic cells in a semiconductor device according to an embodiment of the inventive concept; and

FIGS. 9A to 9C, 10A to 10B, 11A to 11D, 12A to 12D, 13A to 13C, 14A to 14F, 5, and 16 are cross-sectional views illustrating a method of fabricating a semiconductor device, according to an embodiment of the inventive concept.

### DETAILED DESCRIPTION

Example embodiments of the inventive concepts will now be described more fully with reference to the accompanying drawings, in which example embodiments are shown.

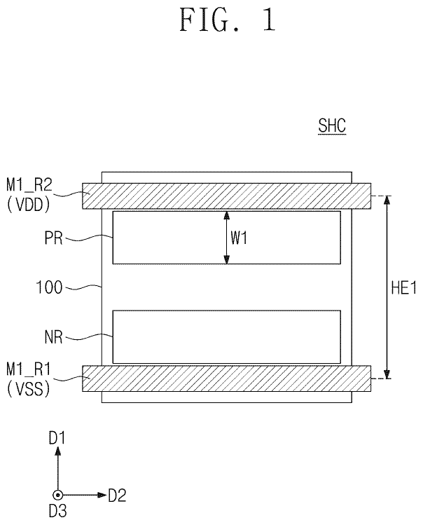

FIGS. 1 to 3 are conceptual diagrams illustrating logic cells in a semiconductor device according to an embodiment of the inventive concept.

Referring to FIG. 1, a single height cell SHC may be provided. For example, a first power line M1_R1 and a second power line M1_R2 may be disposed below a substrate 100. The first power line M1_R1 may be a conduction path, to which a source voltage VSS (e.g., a ground voltage) is provided. The second power line M1_R2 may be a conduction path, to which a drain voltage VDD (e.g., a power voltage) is provided.

The single height cell SHC may be defined between the first power line M1_R1 and the second power line M1_R2. The single height cell SHC may include one PMOSFET region PR and one NMOSFET region NR. For example, the single height cell SHC may have a CMOS structure disposed between the first and second power lines M1_R1 and M1_R2.

Each of the PMOSFET and NMOSFET regions PR and NR may have an active region width W1 in a first direction D1. A length of the single height cell SHC in the first direction D1 may be defined as a first height HE1. The first height HE1 may be substantially equal to a distance (e.g., a pitch) between the first and second power lines M1_R1 and M1_R2.

The single height cell SHC may constitute a single logic cell. In the present specification, the logic cell may mean a logic device (e.g., AND, OR, XOR, XNOR, inverter, and so forth), which is configured to execute a specific function. For example, the logic cell may include transistors constituting the logic device and interconnection lines connecting the transistors to each other.

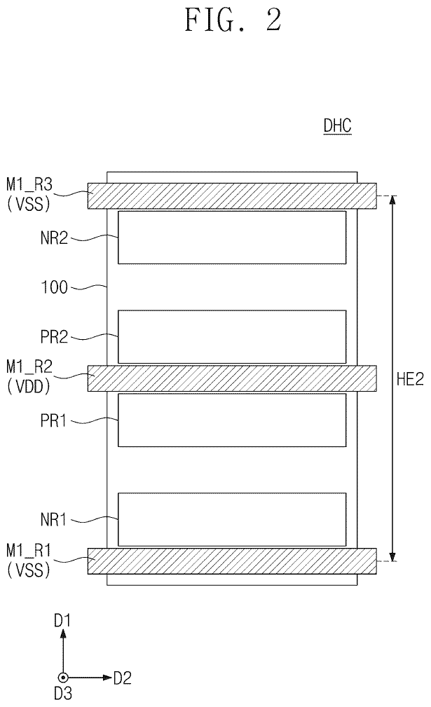

Referring to FIG. 2, a double height cell DHC may be provided. For example, a first power line M1_R1, a second power line M1_R2, and a third power line M1_R3 may be disposed on the substrate 100. The second power line M1_R2 may be disposed between the first power line M1_R1 and the third power line M1_R3. The third power line M1_R3 may be a conduction path, to which the source voltage VSS is provided.

The double height cell DHC may be defined between the first power line M1_R1 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the first power line M1_R1. The second NMOSFET region NR2 may be adjacent to the third power line M1_R3. The first and second PMOSFET regions PR1 and PR2 may be adjacent to the second power line M1_R2. In a plan view, the second power line M1_R2 may be disposed between the first and second PMOSFET regions PR1 and PR2.

A length of the double height cell DHC in the first direction D1 may be defined as a second height HE2. The second height HE2 may be about two times the first height HE1 of FIG. 1. The first and second PMOSFET regions PR1 and PR2 of the double height cell DHC may be combined to serve as a single PMOSFET region. Thus, a channel size of the PMOS transistor of the double height cell DHC may be larger than a channel size of the PMOS transistor of the single height cell SHC of FIG. 1.

For example, the channel size of the PMOS transistor of the double height cell DHC may be about two times the channel size of the PMOS transistor of the single height cell SHC. In this case, the double height cell DHC may be operated at a higher speed than the single height cell SHC. In an embodiment, the double height cell DHC shown in FIG. 2 may be defined as a multi-height cell. The multi-height cell may include a triple height cell whose cell height is about three times that of the single height cell SHC.

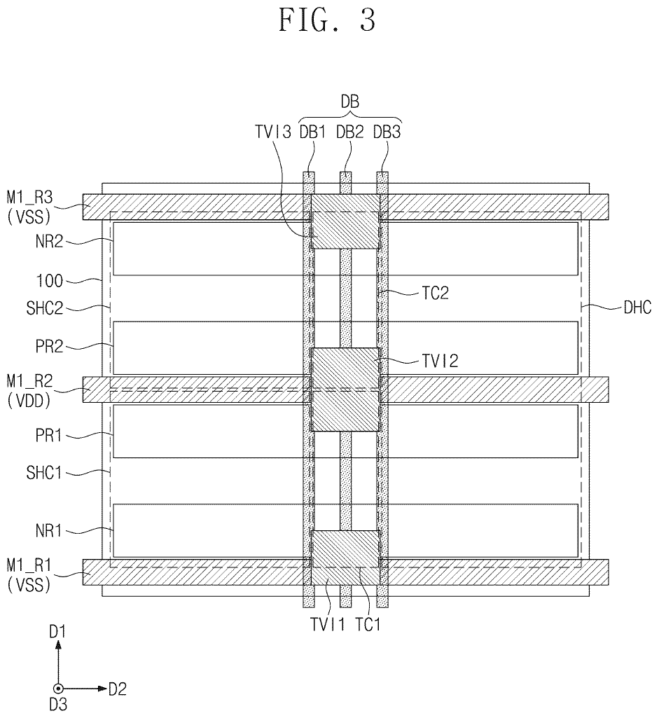

Referring to FIG. 3, a first single height cell SHC1, a second single height cell SHC2, and a double height cell DHC may be two-dimensionally arranged on the substrate 100. The first single height cell SHC1 may be disposed between the first and second power lines M1_R1 and M1_R2. The second single height cell SHC2 may be disposed between the second and third power lines M1_R2 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in a second direction D2.

A first tap cell TC1 may be disposed between the first single height cell SHC1 and the double height cell DHC. A second tap cell TC2 may be disposed between the second single height cell SHC2 and the double height cell DHC. The first tap cell TC1 may be adjacent to the first single height cell SHC1 in the second direction D2, and the second tap cell TC2 may be adjacent to the second single height cell SHC2 in the second direction D2. The first tap cell TC1 and the second tap cell TC2 may be aligned to each other in the first direction D1.

Each of the first and second tap cells TC1 and TC2 may be a cell, which is configured to apply a voltage from a power delivery network, which will be described below, to at least one of the power lines M1_R1 to M1_R3. The tap cell might not include the logic device, unlike the logic cell. For example, the tap cell may be configured to apply a voltage to the power line but may be just a dummy cell that does not serve as a circuit element.

As illustrated in FIG. 3, the first and second tap cells TC1 and TC2 may be disposed in a cell region with the logic cells SHC1, SHC2, and DHC, between the logic cells SHC1, SHC2, and DHC. FIG. 3 illustrates an example of how the first and second tap cells TC1 and TC2 and the logic cells SHC1, SHC2, and DHC can be arranged, but there may be many other possible arrangements for the logic and tap cells within the spirit and scope of the present disclosure.

In an embodiment, a first division structure DB1 may be disposed between the first tap cell TC1 and the first single height cell SHC1 and between the second tap cell TC2 and the second single height cell SHC2. A third division structure DB3 may be disposed between the first tap cell TC1 and the double height cell DHC and between the second tap cell TC2 and the double height cell DHC. A second division structure DB2 may cross the first tap cell TC1 and the second tap cell TC2 in the first direction D1. The second division structure DB2 may be disposed between the first and third division structures DB1 and DB3. The active regions of the logic cells SHC1, SHC2, and DHC may be electrically disconnected from the active regions of the tap cells TC1 and TC2 by the first and third division structures DB1 and DB3.

The first and second tap cells TC1 and TC2 may include first to third penetration via patterns TVI1, TVI2, and TVI3, which are connected to the first to third power lines M1_R1, M1_R2, and M1_R3, respectively. The first penetration via pattern TVI1 may be vertically overlapped with a portion of the first NMOSFET region NR1, and the third penetration via pattern TVI3 may be vertically overlapped with a portion of the second NMOSFET region NR2. The second penetration via pattern TVI2 may be vertically overlapped with portions of the first and second PMOSFET regions PR1 and PR2. In an embodiment, the first to third penetration via patterns TVI1, TVI2, and TVI3 may have a plate shape, in a plan view. FIG. 3 illustrates a simplified example of the first to third penetration via patterns TVI1, TVI2, and TVI3, but the planar shapes of the first to third penetration via patterns TVI1, TVI2, and TVI3 may be variously changed.

The first to third power lines M1_R1, M1_R2, and M1_R3 may be electrically connected to a power delivery network, which is disposed below the substrate 100, through the first to third penetration via patterns TVI1, TVI2, and TVI3.

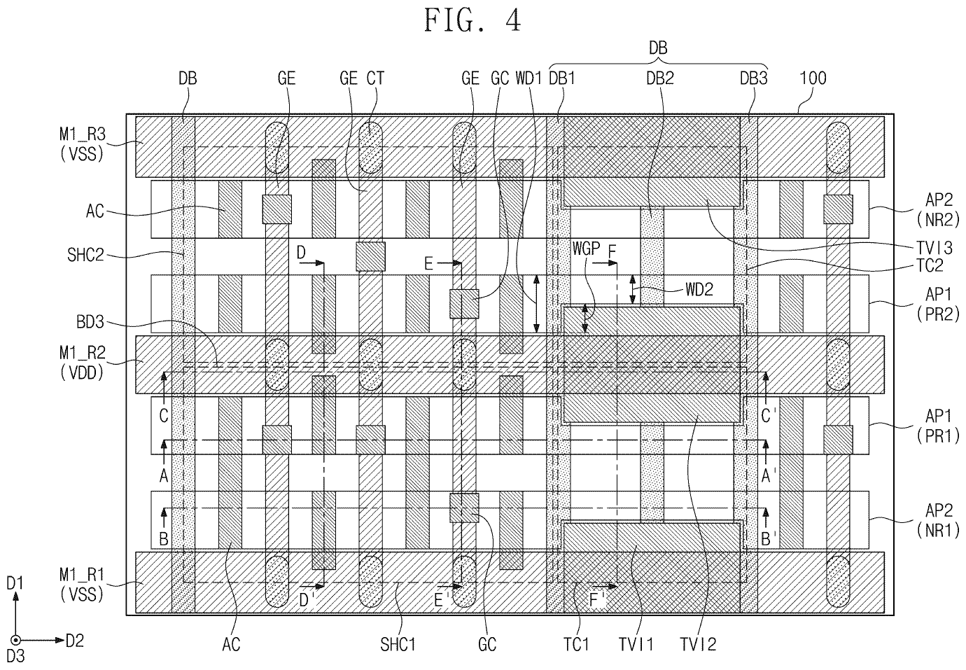

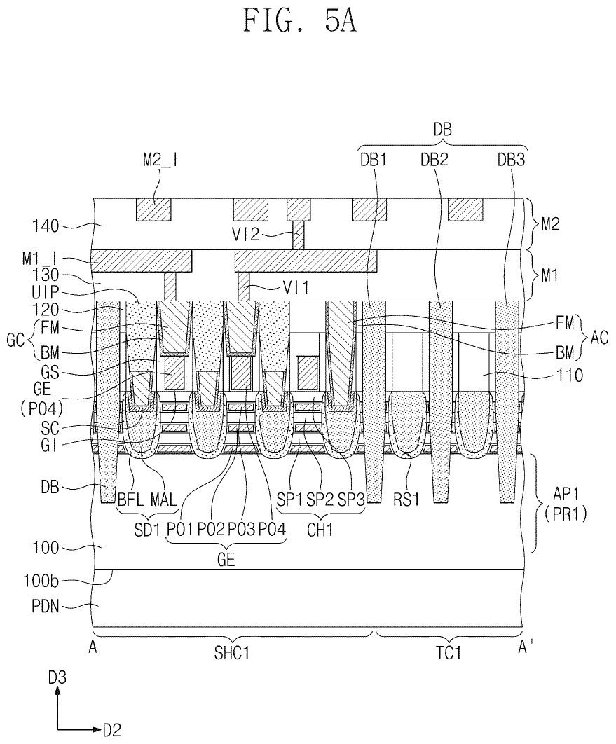

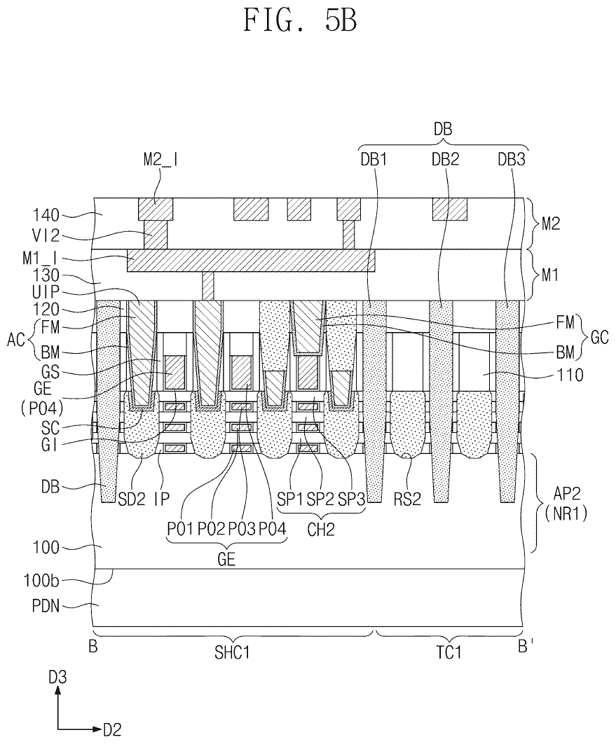

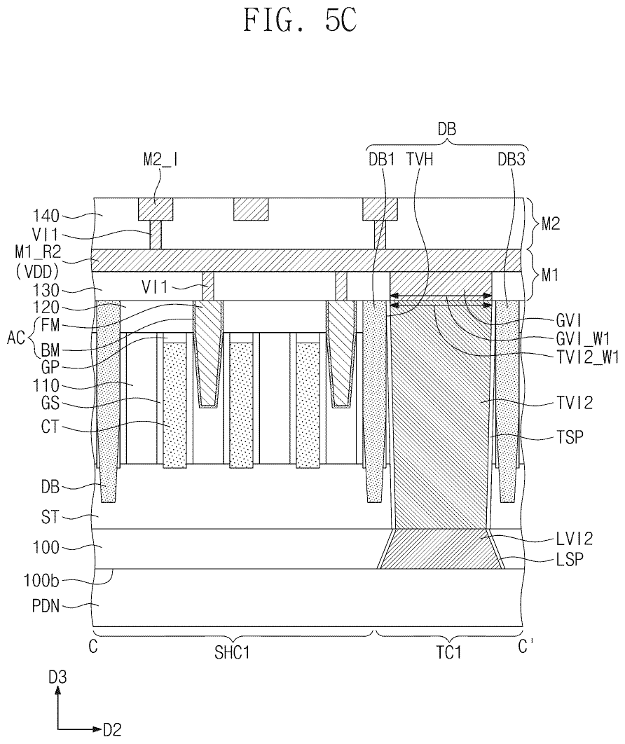

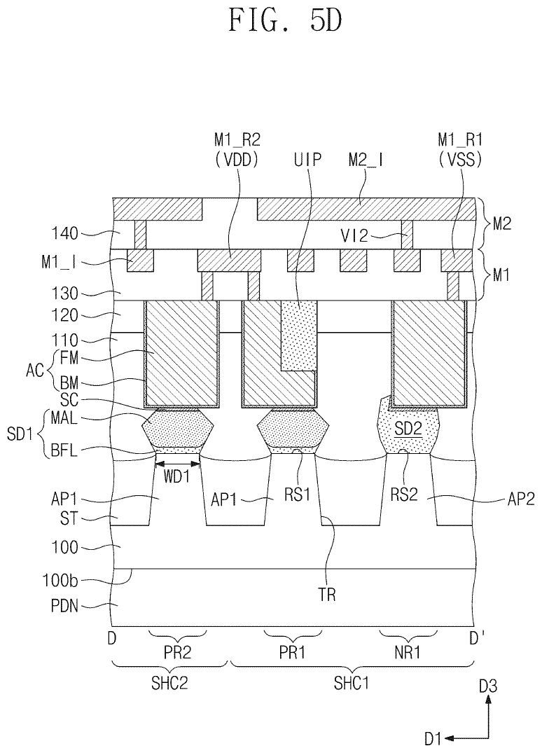

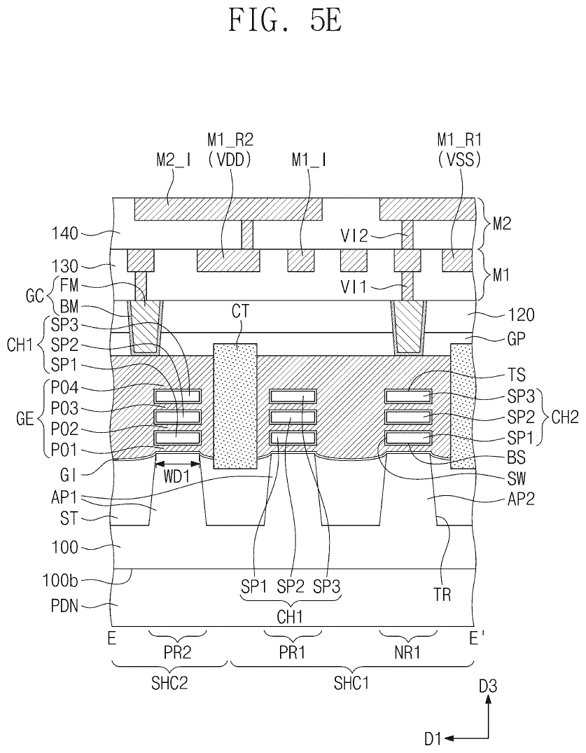

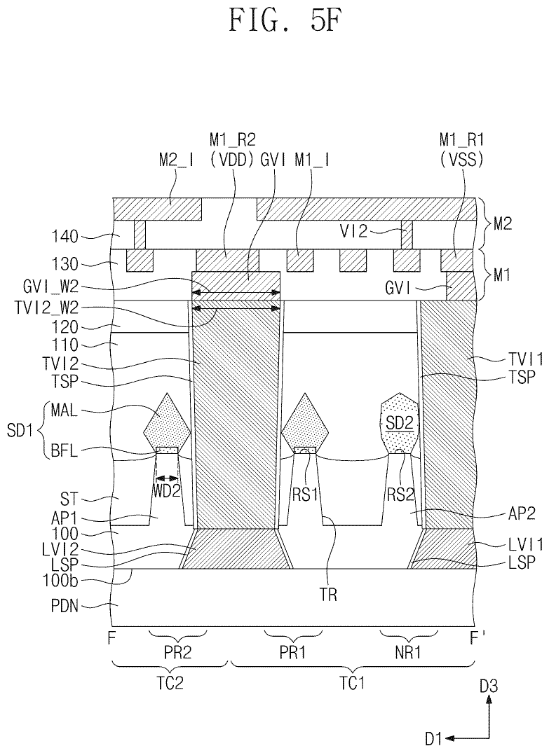

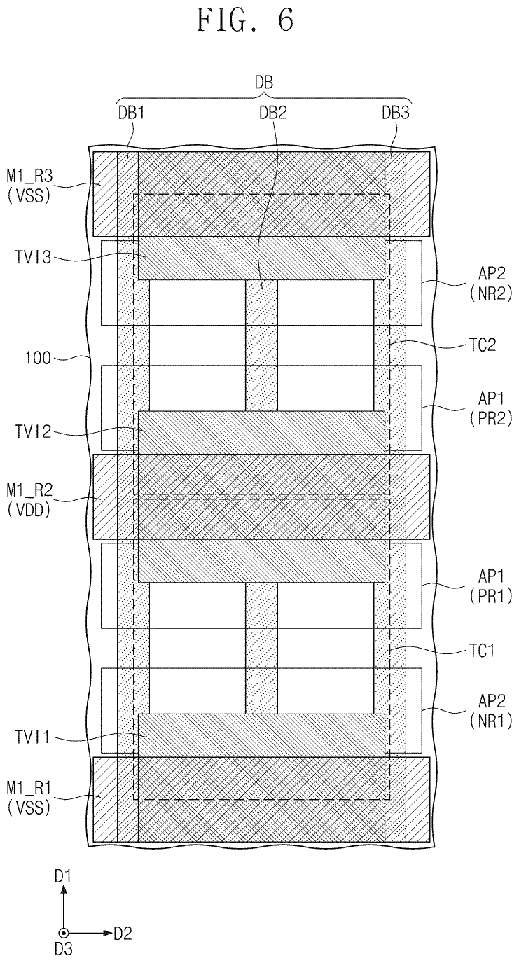

FIG. 4 is a plan view illustrating a semiconductor device, according to an embodiment of the inventive concept. FIGS. 5A to 5F are cross-sectional views taken along lines A-A′, B-B′, C-C′, D-D′, E-E′, and F-F′ of FIG. 4, respectively. FIG. 6 is an enlarged plan view illustrating a portion of FIG. 4. FIGS. 4, 5A to 5F, and 6 illustrate a detailed example of the semiconductor device shown in FIG. 3, including the first and second single height cells SHC1 and SHC2 and the first and second tap cells TC1 and TC2.

Referring to FIG. 4 and FIGS. 5A to 5F, the first and second single height cells SHC1 and SHC2 and the first and second tap cells TC1 and TC2 may be disposed on the substrate 100. Logic transistors constituting a logic circuit may be disposed on each of the first and second single height cells SHC1 and SHC2. Dummy transistors may be disposed on each of the first and second tap cells TC1 and TC2. The substrate 100 may be a semiconductor substrate that is formed of or otherwise includes silicon, germanium, silicon germanium, a compound semiconductor material, or the like. In an embodiment, the substrate 100 may be a silicon wafer. Alternatively, the substrate 100 may be an insulating substrate. In this case, the substrate 100 may include a silicon oxide layer (SiO₂), a silicon nitride layer (SiN), and/or a silicon oxynitride layer (SiON).

The substrate 100 may include the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may be extended in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR, which is formed in an upper portion of the substrate 100. The first active pattern AP1 may be disposed on each of the first and second PMOSFET regions PR1 and PR2. The second active pattern AP2 may be disposed on each of the first and second NMOSFET regions NR1 and NR2. The first and second active patterns AP1 and AP2 may be extended in the second direction D2. Each of the first and second active patterns AP1 and AP2 may be a vertically-protruding portion of the substrate 100. In the case where the substrate 100 is the insulating substrate, a first insulating pattern and a second insulating pattern may be defined by a trench TR, which is formed in an upper portion of the substrate 100. The first and second insulating pattern may be respectively disposed at the same positions as the first and second active patterns AP1 and AP2 described above and may have the same shapes as the first and second active patterns AP1 and AP2 described above. For example, the first and second insulating patterns may be elements corresponding to the first and second active patterns AP1 and AP2 described above.

Referring back to FIGS. 4 and 6, the first and second active patterns AP1 and AP2 may be spaced apart from each other in the first direction D1. The first and second active patterns AP1 and AP2 may be extended in the second direction D2 and may cross the first single height cell SHC1 and the first tap cell TC1. The first and second active patterns AP1 and AP2 may be extended in the second direction D2 and may cross the second single height cell SHC2 and the second tap cell TC2.

The first active pattern AP1 on the first or second single height cell SHC1 or SHC2 may have a first width WD1 in the first direction D1. The first width WD1 may be defined as a vertical distance of the first active pattern AP1 on the single height cell SHC1 or SHC2 measured in the first direction D1. The first active pattern AP1 on the first or second tap cell TC1 or TC2 may have a second width WD2 in the first direction D1. The second width WD2 may be defined as a vertical distance of the first active pattern AP1 on the first or second tap cell TC1 or TC2 measured in the first direction D1. The first width WD1 may correspond to a width of nanosheets, which will be described below, and may correspond to a channel size of the single height cell described above.

As an example, the first width WD1 may be larger than the second width WD2. As an example, the first width WD1 may be substantially equal to the second width WD2. The first width WD1 may be 1.2 to 2.5 (for example, 1.2 to 1.75) times the second width WD2. A difference WGP between the first and second widths WD1 and WD2 may range from 0 nm to 15 nm.

Owing to the difference WGP of the first and second widths WD1 and WD2, the second penetration via pattern TVI2 of the tap cell TC1 or TC2, which will be described below, might not be vertically overlapped with the first active pattern AP1. For example, since the second width WD2 is smaller than the first width WD1, the first or second active pattern AP1 or AP2 may be a bar-shaped pattern whose width is partially reduced.

For example, on the first PMOSFET region PR1, the first active pattern AP1 on the first tap cell TC1 may have an inverted U-shaped structure, in a plan view. On the second PMOSFET region PR2, the first active pattern AP1 on the second tap cell TC2 may have a U-shaped structure, in a plan view.

A device isolation layer ST may fill the trench TR. The device isolation layer ST may be formed of or may otherwise include silicon oxide. The device isolation layer ST might not cover first and second channel patterns CH1 and CH2 to be described below.

A first channel pattern CH1 may be disposed on the first active pattern AP1. A second channel pattern CH2 may be disposed on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may be formed of or may include silicon (Si), germanium (Ge), and/or silicon germanium (SiGe). For example, each of the first to third semiconductor patterns SP1, SP2, and SP3 may be formed of or may otherwise include crystalline silicon. In an embodiment, each of the first to third semiconductor patterns SP1, SP2, and SP3 may be a nanosheet.

A plurality of first source/drain patterns SD1 may be disposed on the first active pattern AP1. A plurality of first recesses RS1 may be formed in an upper portion of the first active pattern AP1. The first source/drain patterns SD1 may be disposed in the first recesses RS1, respectively. The first source/drain patterns SD1 may be impurity regions of a first conductivity type (e.g., p-type). The first channel pattern CH1 may be interposed between each pair of the first source/drain patterns SD1. For example, each pair of the first source/drain patterns SD1 may be connected to each other by the stacked first to third semiconductor patterns SP1, SP2, and SP3.

A plurality of second source/drain patterns SD2 may be disposed on the second active pattern AP2. A plurality of second recesses RS2 may be formed in an upper portion of the second active pattern AP2. The second source/drain patterns SD2 may be disposed in the second recesses RS2, respectively. The second source/drain patterns SD2 may be impurity regions of a second conductivity type (e.g., n-type). The second channel pattern CH2 may be interposed between a pair of the second source/drain patterns SD2. For example, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth SEG process. As an example, a top surface of each of the first and second source/drain patterns SD1 and SD2 may be positioned at substantially the same level as a top surface of the third semiconductor pattern SP3. However, in an embodiment, the top surface of each of the first and second source/drain patterns SD1 and SD2 may be higher than the top surface of the third semiconductor pattern SP3.

The first source/drain patterns SD1 may include a semiconductor material (e.g., SiGe) whose lattice constant is greater than that of the substrate 100. In this case, the pair of the first source/drain patterns SD1 may exert a compressive stress on the first channel patterns CH1 therebetween. The second source/drain patterns SD2 may be formed of or may otherwise include the same semiconductor element (e.g., Si) as the substrate 100.

Each of the first source/drain patterns SD1 may include a buffer layer BFL and a main layer MAL on the buffer layer BFL. Referring back to FIG. 5A, the buffer layer BFL may cover an inner surface the first recess RS1. In an embodiment, the buffer layer BFL may have a substantially conformal thickness (e.g., a substantially consistent thickness across its entirety). For example, a thickness of the buffer layer BFL, which is measured in the third direction D3 on a bottom of the first recess RS1, may be substantially equal to a thickness of the buffer layer BFL, which is measured in the second direction D2 at a top level of the first recess RS1.

In an embodiment, the buffer layer BFL may have a decreasing thickness in an upward direction. For example, the thickness of the buffer layer BFL, which is measured in the third direction D3 on the bottom of the first recess RS1, may be larger than a thickness of the buffer layer BFL, which is measured in the second direction D2 at the top level of the first recess RS1. In addition, the buffer layer BFL may have a ‘U’-shaped section corresponding to a profile of the first recess RS1.

The main layer MAL may fill most of an unfilled region of the first recess RS1 covered with the buffer layer BFL. The main layer MAL may have a volume that is greater than that of the buffer layer BFL. Each of the buffer and main layers BFL and MAL may be formed of or may otherwise include silicon germanium (SiGe). For example, the buffer layer BFL may contain a relatively low concentration of germanium (Ge). In an embodiment, the buffer layer BFL may contain only silicon (Si), without germanium (Ge). A germanium concentration of the buffer layer BFL may range from 0 at % to 10 at % (where at % represents the atomic percent).

The main layer MAL may contain a relatively high concentration of germanium. In an embodiment, the germanium concentration of the main layer MAL may range from 30 at % to 70 at %. The germanium concentration of the main layer MAL may increase in the third direction D3. For example, a portion of the main layer MAL, which is adjacent to the buffer layer BFL, may have a germanium concentration of about 40 at %, and an upper portion of the main layer MAL may have a germanium concentration of about 60 at %.

Each of the buffer and main layers BFL and MAL may contain an impurity (e.g., boron, gallium, or indium) that allows the first source/drain pattern SD1 to have a p-type conductivity. The impurity concentration of each of the buffer and main layers BFL and MAL may range from 1E18 (1×10¹⁸) atoms/cm³ to 5E22 (5×10²²) atoms/cm³. The impurity concentration of the main layer MAL may be higher than the impurity concentration of the buffer layer BFL.

The buffer layer BFL may prevent a stacking fault between the substrate 100 (i.e., the first active pattern AP1) and the main layer MAL and between the first to third semiconductor patterns SP1, SP2, and SP3 and the main layer MAL. The stacking fault may lead to an increase of a channel resistance. The buffer layer BFL may be used to protect the main layer MAL in a process of replacing second semiconductor layers SAL with first to third inner electrodes PO1, PO2, and PO3 of a gate electrode GE, as will be described below. For example, the buffer layer BFL may prevent an etchant material, which is used to remove the second semiconductor layers SAL, from entering and etching the main layer MAL.

Each of the second source/drain patterns SD2 may be formed of or may otherwise include silicon (Si). The second source/drain pattern SD2 may further contain impurities (e.g., phosphorus, arsenic, or antimony) that allow the second source/drain pattern SD2 to have an n-type conductivity. The impurity concentration of the second source/drain pattern SD2 may range from 1E18 (1×10¹⁸) atom/cm³ to 5E22 (5×10²²) atom/cm³.

The gate electrodes GE may cross the first and second channel patterns CH1 and CH2 and to extend in the first direction D1. The gate electrodes GE may be arranged at a first pitch in the second direction D2. Each of the gate electrodes GE may be vertically overlapped with the first and second channel patterns CH1 and CH2.

The gate electrode GE may include a first inner electrode POI interposed between the active pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 5E, the gate electrode GE may be disposed on a top surface TS, a bottom surface BS, and opposite side surfaces SW of each of the first to third semiconductor patterns SP1, SP2, and SP3. For example, the transistor according to the present embodiment may be a three-dimensional field effect transistor (e.g., MBCFET or GAAFET) in which the gate electrode GE surrounds the channel pattern in three dimensions.

Gate cutting patterns CT may be disposed on a boundary region between the first and second single height cells SHC1 and SHC2. The gate cutting patterns CT may be arranged at the first pitch along the boundary. In a plan view, the gate cutting patterns CT may be overlapped with the gate electrodes GE, respectively. The gate cutting patterns CT may be formed of or may otherwise include at least one insulating material such as, for example, silicon oxide, silicon nitride, or combinations thereof.

In an embodiment, the gate cutting pattern CT may be disposed between the division structures DB and may be a bar-shaped pattern that is longer than a first pitch. For example, the gate cutting pattern CT may be a line- or bar-shaped pattern, which is extended in the second direction D2 in a plan view. In an embodiment, the gate cutting pattern CT may cross over the device isolation layer ST and to separate the gate electrodes GE from each other.

The gate electrode GE on the first single height cell SHC1 may be separated from the gate electrode GE on the second single height cell SHC2 by the gate cutting pattern CT. The gate cutting pattern CT may be interposed between the gate electrodes GE, which are disposed on the first and second single height cells SHC1 and SHC2 aligned to each other in the first direction D1. For example, the gate electrode GE extending in the first direction DI may be divided into a plurality of the gate electrodes GE by the gate cutting patterns CT.

Referring back to FIG. 4 and FIGS. 5A to 5F, a pair of gate spacers GS may be respectively disposed on opposite side surfaces of the outer electrode PO4 of the gate electrode GE. The gate spacers GS may be extended along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described below. The gate spacers GS may be formed of or may otherwise include at least one of SiCN, SiCON, or SiN. In an embodiment, the gate spacers GS may be a multi-layered structure, which includes at least two different materials selected from SiCN, SiCON, and SiN.

A gate capping pattern GP may be disposed on the gate electrode GE. The gate capping pattern GP may be extended along the gate electrode GE or in the first direction D1. The gate capping pattern GP may be formed of or may otherwise include a material having an etch selectivity with respect to first and second interlayer insulating layers 110 and 120, which will be described below. For example, the gate capping pattern GP may be formed of or may otherwise include SiON, SiCN, SiCON, and/or SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and opposite side surfaces SW of each of the first to third semiconductor patterns SP1, SP2, and SP3. The gate insulating layer GI may cover the top surface of the device isolation layer ST below the gate electrode GE.

In an embodiment, the gate insulating layer GI may include a silicon oxide layer, a silicon oxynitride layer, and/or a high-k dielectric layer. The high-k dielectric layer may be formed of or may otherwise include at least one of high-k dielectric materials whose dielectric constants are higher than that of silicon oxide. For example, the high-k dielectric material may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and/or lead zinc niobate.

The gate electrode GE may include a first metal pattern and a second metal pattern disposed on the first metal pattern. The first metal pattern may be disposed on the gate insulating layer GI and may be adjacent to the first to third semiconductor patterns SP1, SP2, and SP3. The first metal pattern may include a work-function metal (e.g., a metal chosen specifically for its work function value), which can be used to adjust a threshold voltage of the transistor. By adjusting a thickness and composition of the first metal pattern, it may be possible to realize a transistor having a desired threshold voltage. For example, the first to third inner electrodes PO1, PO2, and PO3 of the gate electrode GE may be composed of the first metal pattern including the work-function metal.

The first metal pattern may include a metal nitride layer. For example, the first metal pattern may include a layer that is composed of at least one metal such as titanium (Ti), tantalum (Ta), aluminum (Al), tungsten (W) and/or molybdenum (Mo), and further composed of nitrogen (N). In an embodiment, the first metal pattern may further include carbon (C). The first metal pattern may include a plurality of work function metal layers which are stacked upon one another.

The second metal pattern may be formed of or may otherwise include a metal whose resistance is lower than that of the first metal pattern. For example, the second metal pattern may be formed of or may otherwise include tungsten (W), aluminum (Al), titanium (Ti), and/or tantalum (Ta). In an embodiment, the outer electrode PO4 of the gate electrode GE may include the first metal pattern and the second metal pattern disposed on the first metal pattern.

Referring back to FIG. 5B, inner spacers IP may be disposed on the first and second NMOSFET regions NR1 and NR2. For example, the inner spacers IP may be disposed on the second active pattern AP2. The inner spacers IP may be respectively interposed between the second source/drain pattern SD2 and the first to third inner electrodes PO1, PO2, and PO3 of the gate electrode GE. The inner spacers IP may be in direct contact with the second source/drain pattern SD2. Each of the first to third inner electrodes PO1, PO2, and PO3 of the gate electrode GE may be spaced apart from the second source/drain pattern SD2 by the inner spacer IP.

A first interlayer insulating layer 110 may be disposed on the substrate 100. The first interlayer insulating layer 110 may cover the gate spacers GS and the first and second source/drain patterns SD1 and SD2. The first interlayer insulating layer 110 may have a top surface that is substantially coplanar with the top surface of the gate capping pattern GP and the top surface of the gate spacer GS. A second interlayer insulating layer 120 may be formed on the first interlayer insulating layer 110 and may cover the gate capping pattern GP. A third interlayer insulating layer 130 may be disposed on the second interlayer insulating layer 120. A fourth interlayer insulating layer 140 may be disposed on the third interlayer insulating layer 130. In an embodiment, at least one of the first to fourth interlayer insulating layers 110 to 140 may include a silicon oxide layer.

The division structures DB may be respectively disposed on boundaries between the cells. For example, the first division structure DB1 may be disposed between the first and second single height cells SHC1 and SHC2 and the first and second tap cells TC1 and TC2. The third division structure DB3 may be disposed between the first and second tap cells TC1 and TC2 and other logic cells adjacent thereto. The second division structure DB2 may be disposed between the first and third division structures DB1 and DB3. For example, the first and third division structures DB1 and DB3 may be disposed on opposite borders of each of the first and second tap cells TC1 and TC2. Each of the first and second tap cells TC1 and TC2 may be disposed on a plurality of division structures DB1, DB2, and DB3.

The division structures DB may be extended in the first direction DI and may run parallel to the gate electrodes GE. A pitch between the division structure DB and the gate electrode GE adjacent thereto may be equal to the first pitch. A pitch between the first and second division structures DB1 and DB2 or a pitch between the second and third division structures DB2 and DB3 may be equal to the first pitch. For example, a distance between the first and second division structures DB1 and DB2 may be substantially equal to a distance between the second and third division structures DB2 and DB3.

A width of each of the first and second tap cells TC1 and TC2 in the second direction D2 may be 1.5 to 2.5 times the first pitch, and in an embodiment, it may be two times the first pitch.

The division structure DB may penetrate the first and second interlayer insulating layers 110 and 120 and may be extended into the first and second active patterns AP1 and AP2. The division structure DB may penetrate an upper portion of each of the first and second active patterns AP1 and AP2. A bottom surface of each of the division structures DB may be located at a level that is higher than a bottom surface of a penetration via pattern TVI1 or TVI2, which will be described below, when measured in the third direction D3. For example, since the penetration via pattern TVI1 or TVI2 is extended into the first and second active patterns AP1 and AP2 to a large depth that is deeper than the division structures DB, a bottom surface of the penetration via pattern TVI1 or TVI2 may be located at a level lower than the bottom surface of each of the division structures DB1, DB2, and DB3 in the third direction D3. The division structure DB may electrically separate an active region of one cell from an active region of a neighboring cell.

Active contacts AC may penetrate the first and second interlayer insulating layers 110 and 120 and may be electrically connected to the first and second source/drain patterns SD1 and SD2, respectively. A pair of the active contacts AC may be respectively disposed at both sides of the gate electrode GE. In a plan view, the active contact AC may be a bar-shaped pattern that is extended in the first direction D1.

The active contact AC may be a self-aligned contact. For example, the active contact AC may be formed by a self-alignment process using the gate capping pattern GP and the gate spacer GS. For example, the active contact AC may cover at least a portion of the side surface of the gate spacer GS. The active contact AC may cover a portion of the top surface of the gate capping pattern GP.

Metal-semiconductor compound layers SC (e.g., silicide layers) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or may otherwise include at least one of titanium silicide, tantalum silicide, tungsten silicide, nickel silicide, and/or cobalt silicide.

Gate contacts GC may penetrate the second interlayer insulating layer 120 and the gate capping pattern GP and may be electrically connected to the gate electrodes GE, respectively. In a plan view, two gate contacts GC on the first single height cell SHC1 may be overlapped with the first PMOSFET region PR1. For example, the two gate contacts GC on the first single height cell SHC1 may be disposed on the first active pattern AP1 (e.g., see FIG. 5A). In a plan view, one gate contact GC on the first single height cell SHC1 may be overlapped with the first NMOSFET region NR1. For example, the one gate contact GC on the first single height cell SHC1 may be disposed on the second active pattern AP2 (e.g., see FIG. 5B).

The gate contact GC may be freely disposed on the gate electrode GE, without any restrictions on its position. For example, the gate contacts GC on the second single height cell SHC2 may be respectively disposed on the second PMOSFET region PR2, the second NMOSFET region NR2, and the device isolation layer ST filling the trench TR (e.g., see FIG. 4).

In an embodiment, referring to FIGS. 5A and 5D, an upper portion of the active contact AC adjacent to the gate contact GC may be filled with an upper insulating pattern UIP. A bottom surface of the upper insulating pattern UIP may be lower than a bottom surface of the gate contact GC. For example, a top surface of the active contact AC adjacent to the gate contact GC may be formed at a level, which is lower than the bottom surface of the gate contact GC, by the upper insulating pattern UIP. Accordingly, it may be possible to prevent the gate contact GC and the active contact AC, which are adjacent to each other, from being in contact with each other and thereby to prevent a short circuit from occurring therebetween.

Each of the active and gate contacts AC and GC may include a conductive pattern FM and a barrier pattern BM enclosing the conductive pattern FM. For example, the conductive pattern FM may be formed of or may otherwise include a metal such as aluminum, copper, tungsten, molybdenum, and/or cobalt. The barrier pattern BM may cover side and bottom surfaces of the conductive pattern FM. In an embodiment, the barrier pattern BM may include a metal layer and a metal nitride layer. The metal layer may be formed of or may otherwise include titanium, tantalum, tungsten, nickel, cobalt, and/or platinum. The metal nitride layer may be formed of or may otherwise include titanium nitride (TiN), tantalum nitride (TaN), tungsten nitride (WN), nickel nitride (NiN), cobalt nitride (CoN), and/or platinum nitride (PtN).

Referring back to FIGS. 4, 5C, and 5F, a first metal layer M1 may be disposed in the third interlayer insulating layer 130. The first metal layer M1 may include the first to third power lines M1_R1, M1_R2, and M1_R3.

The first to third power lines M1_R1, M1_R2, and M1_R3 may be extended in the second direction D2 and may run in parallel to each other. The first power line M1_R1 may be disposed on a border of the first single height cell SHC1. The second power line M1_R2 may be disposed on a boundary between the first and second single height cells SHC1 and SHC2. The third power line M1_R3 may be disposed on a border of the second single height cell SHC2.

Referring back to FIGS. 5C and 5D, the second power line M1_R2 may be electrically connected to at least one active contact AC. A first via VI1 may be disposed between the second power line M1_R2 and the at least one active contact AC.

Referring back to FIGS. 4, 5C, and 5F, the first to third penetration via patterns TVI1, TVI2, and TVI3, which are respectively and electrically connected to the first to third power lines M1_R1, M1_R2, and M1_R3, may be disposed on the first and second tap cells TC1 and TC2.

For example, the second penetration via pattern TVI2 may be vertically extended from the second interlayer insulating layer 120 to the trench TR of the substrate 100. The second penetration via pattern TVI2 may penetrate the first and second interlayer insulating layers 110 and 120 and the device isolation layer ST. A top surface of the second penetration via pattern TVI2 may be coplanar with a top surface of the second interlayer insulating layer 120. A bottom surface of the second penetration via pattern TVI2 may be located at a level that is lower than a bottom surface of the trench TR in the third direction D3. A giant via pattern GVI may be disposed between the second penetration via pattern TVI2 and the second power line M1_R2. The second penetration via pattern TVI2 and the second power line M1_R2 may be electrically connected to each other through the giant via pattern GVI.

A width of the second penetration via pattern TVI2 in the second direction D2 may be equal to a distance between the first and third division structures DB1 and DB3. For example, the width of the second penetration via pattern TVI2 in the second direction D2 may be two times the pitch between each adjacent pair of the first to third division structures DB1, DB2, and DB3. The width of the second penetration via pattern TVI2 in the second direction D2 may be two times the first pitch.

The largest width GVI_W1 of the giant via pattern GVI in the second direction D2 may be smaller than or equal to the largest width TVI2_W1 of the second penetration via pattern TVI2 in the second direction D2. The largest width GVI_W2 of the giant via pattern GVI in the first direction D1 may be smaller than or equal to the largest width TVI2_W2 of the second penetration via pattern TVI2 in the first direction D1. The giant via pattern GVI and the second penetration via pattern TVI2 may be vertically overlapped with each other. As an example, the giant via pattern GVI and the second penetration via pattern TVI2 may have a rectangular shape, in a plan view.

Lower via patterns may penetrate the substrate 100. The lower via patterns may be connected to the first to third penetration via patterns TVI1, TVI2, and TVI3, respectively. For example, a first lower via pattern LVI1 and the first penetration via pattern TVI1 may be vertically overlapped with each other, and a second lower via pattern LVI2 and the second penetration via pattern TVI2 may be vertically overlapped with each other.

In an embodiment, the second lower via pattern LVI2 may be vertically extended from a bottom surface 100b of the substrate 100 to the bottom surface of the second penetration via pattern TVI2. A top surface of the second lower via pattern LVI2 may be in contact with a bottom surface of the second penetration via pattern TVI2.

The largest width of each of the lower via patterns LVI1 and LVI2 in the second direction D2 may be larger than the largest width of each of the penetration via patterns TVI1 and TVI2 in the second direction D2.

In an embodiment, the penetration via patterns TVI1 to TVI3 and the lower via patterns LVI1 and LVI2 may include the same metal. For example, the penetration via patterns TVI1 to TVI3 and the lower via patterns LVI1 and LVI2 may be formed of or may otherwise include copper.

In an embodiment, the penetration via patterns TVI1 to TVI3 and the lower via patterns LVI1 and LVI2 may include different metals from each other. For example, the penetration via patterns TVI1 to TVI3 may be formed of or may otherwise include molybdenum or ruthenium, and the lower via patterns LVI1 and LVI2 may be formed of or may otherwise include copper.

The penetration via patterns TVI1 to TVI3 and the lower via patterns LVI1 and LVI2 may be self-aligned to each other. For example, a center line of each of the penetration via patterns TVI1 to TVI3 may be aligned to a center line of a corresponding one of the lower via patterns LVI1 and LVI2.

As a height in the third direction D3 increases, the penetration via patterns TVI1-TVI3 may have an increasing width. For example, as a distance to the bottom surface 100b of the substrate 100 decreases, the width of the penetration via patterns TVI1-TVI3 may decrease. As the distance to the bottom surface 100b of the substrate 100 decreases, a width of the lower via patterns LVI1 and LVI2 may increase. For example, the penetration via patterns TVI1-TVI3 and the lower via patterns LVI1 and LVI2 may form an hourglass-shaped structure.

Upper spacers TSP may be disposed on side surfaces of the penetration via patterns TVI1-TVI3. The upper spacer TSP may be formed of or may otherwise include a silicon-based insulating material (e.g., silicon oxide, silicon nitride, or silicon oxynitride). Lower spacers LSP may be disposed on side surfaces of the lower via patterns LVI1 and LVI2. The lower spacer LSP may be formed of or may otherwise include a silicon-based insulating material (e.g., silicon oxide, silicon nitride, or silicon oxynitride).

A power delivery network layer PDN may be disposed on the bottom surface 100b of the substrate 100. The power delivery network layer PDN may include a plurality of lower interconnection lines, which are electrically connected to the lower via patterns LVI1 and LVI2. For example, the power delivery network layer PDN may be electrically connected to the first to third power lines M1_R1, M1_R2, and M1_R3.

In an embodiment, the power delivery network layer PDN may include an interconnection network, which is used to apply the source voltage VSS to the first and third power lines M1_R1 and M1_R3. The power delivery network layer PDN may include an interconnection network, which is used to apply the drain voltage VDD to the second power line M1_R2.

Referring back to FIG. 4 and FIGS. 5A to 5F, the first metal layer M1 may further include first interconnection lines M1_I. The first interconnection lines M1_I may be extended in the second direction D2 and may run parallel to each other.

The first metal layer M1 may further include the first vias VI1. The first vias VI1 may be respectively disposed below the first interconnection lines M1_I of the first metal layer M1. The active contact AC and the first interconnection line M1_I may be electrically connected to each other through the first via VI1. The gate contact GC and the first interconnection line M1_I may be electrically connected to each other through the first via VI1.

The first interconnection line M1_I of the first metal layer M1 and the first via VI1 thereunder may be separately formed by different processes. For example, each of the first interconnection line M1_I and the first via VI1 of the first metal layer M1 may be formed by a single damascene process. The semiconductor device according to the present embodiment may be fabricated using a sub-20 nm process.

A second metal layer M2 may be disposed in a fourth interlayer insulating layer 140. The second metal layer M2 may include a plurality of second interconnection lines M2_I. Each of the second interconnection lines M2_I of the second metal layer M2 may be a line- or bar-shaped pattern that is extended in the first direction D1. For example, the second interconnection lines M2_I may be extended in the first direction D1 and may run parallel to each other.

The second metal layer M2 may further include second vias VI2, which are respectively disposed below the second interconnection lines M2_I. The first interconnection line M1_I of the first metal layer M1 and the second interconnection line M2_I of the second metal layer M2 may be electrically connected to each other through the second via VI2. As an example, the second interconnection line M2_I of the second metal layer M2 and the second via VI2 thereunder may be formed by a dual damascene process.

The first interconnection line M1_I of the first metal layer M1 and the second interconnection line M2_I of the second metal layer M2 may be formed of or may otherwise include the same conductive material or different conductive materials. For example, the first interconnection line M1_I of the first metal layer M1 and the second interconnection line M2_I of the second metal layer M2 may be formed of or may otherwise include at least one metal such as aluminum, copper, tungsten, molybdenum, ruthenium, and/or cobalt. A plurality of metal layers (e.g., M3, M4, M5, and so forth) may be additionally stacked on the fourth interlayer insulating layer 140. Each of the stacked metal layers may include interconnection lines, which are used as routing paths between cells.

According to an embodiment of the inventive concept, the penetration via pattern (e.g., TVI1 to TVI3) may be formed through a process that is independent of a process to form the lower via pattern (e.g., LVI1 and LVI2). For example, a vertical contact, which is extended from the power delivery network layer PDN to the first metal layer M1, may be composed of two distinct via patterns (i.e., the penetration and lower via patterns), which are formed through the independent processes. As a result, it may be possible to improve a filling property in a metal-filling step, which is performed to form the vertical contact (e.g., TVI and LVI) having a high aspect ratio, and thereby to increase the reliability characteristics of the semiconductor device.

According to an embodiment of the inventive concept, the vertical contact may include the two distinct via patterns (e.g., the penetration and lower via patterns TVI and LVI), which are respectively formed on front and rear surfaces of the substrate 100. In this case, it may be possible to reduce a chip area that is required to form the vertical contact. Hence, a size of a tab cell may be reduced, as will be described below.

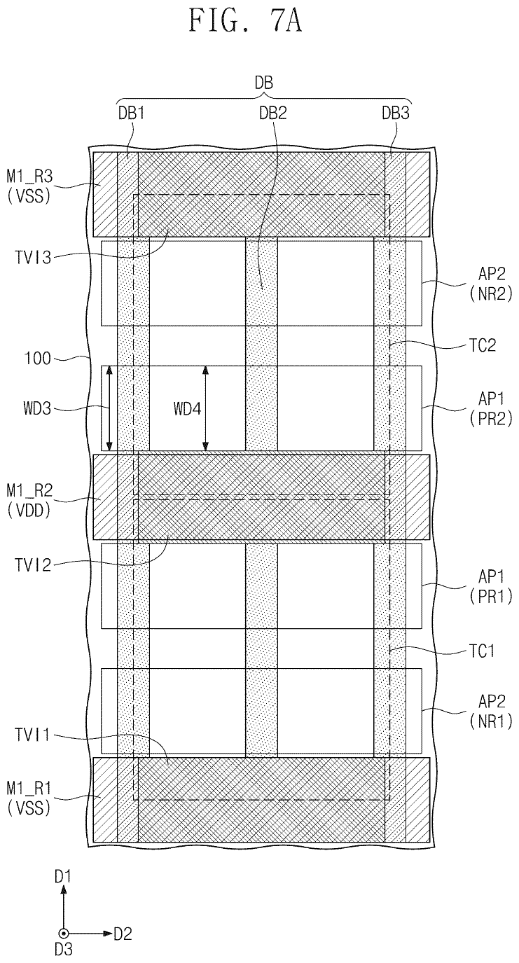

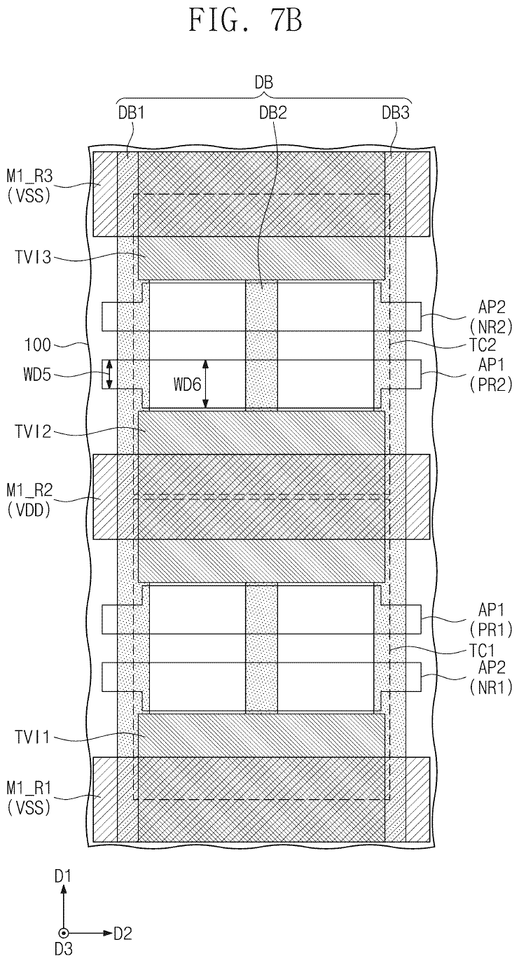

Hereinafter, some examples of the semiconductor device of FIG. 6, according to embodiments of the inventive concept, will be described with reference to FIGS. 7A and 7B. In the following description, to the extent that an element is not described in detail with respect to this figure, it may be understood that the element is at least similar to a corresponding element that has been described elsewhere within the present disclosure.

Referring to FIG. 7A, the first active pattern AP1 on the first or second single height cell SHC1 or SHC2 may have a third width WD3 in the first direction D1. The third width WD3 may be defined as a vertical distance of the first active pattern AP1 on the single height cell SHC1 or SHC2 measured in the first direction D1. The first active pattern AP1 on the first or second tap cell TC1 or TC2 may have a fourth width WD4 in the first direction D1. The fourth width WD4 may be defined as a vertical distance of the first active pattern AP1 on the first or second tap cell TC1 or TC2 measured in the first direction D1.

In an embodiment, the third width WD3 may be substantially equal to the fourth width WD4. In this case, the first or second active pattern AP1 or AP2 may be a bar-shaped pattern that is extended in the second direction D2.

The first to third penetration via patterns TVI1, TVI2, and TVI3 may be vertically overlapped with the first to third power lines M1_R1, M1_R2, and M1_R3, and the first to third penetration via patterns TVI1, TVI2, and TVI3 may be vertically overlapped with the first or second active pattern AP1 or AP2. For example, a width of each of the first to third penetration via patterns TVI1, TVI2, and TVI3 in the first direction D1 may be equal to a width of each of the first to third power lines M1_R1, M1_R2, and M1_R3 in the first direction D1.

Referring to FIG. 7B, the first active pattern AP1 on the first or second single height cell SHC1 or SHC2 may have a fifth width WD5 in the first direction D1. The fifth width WD5 may be defined as a vertical distance of the first active pattern AP1 on the single height cell SHC1 or SHC2 in the first direction D1. The first active pattern AP1 on the first or second tap cell TC1 or TC2 may have a sixth width WD6 in the first direction D1. The sixth width WD6 may be defined as a vertical distance of the first active pattern AP1 on the first or second tap cell TC1 or TC2 in the first direction D1.

In an embodiment, the fifth width WD5 may be smaller than the sixth width WD6. The sixth width WD6 may be 1.2 to 2.5 (for example, 1.2 to 1.75) times the fifth width WD5. A difference between the fifth and sixth widths WD5 and WD6 may be 0 nm to 15 nm.

Due to the difference between the fifth and sixth widths WD5 and WD6, the second penetration via pattern TVI2 of the tap cells TC1 and TC2, which will be described below, might not be vertically overlapped with the first active pattern AP1. For example, since the fifth width WD5 is smaller than the sixth width WD6, the first or second active pattern AP1 or AP2 may be a bar-shaped pattern whose width is partially reduced.

On the first PMOSFET region PR1, the first active pattern AP1 on the first tap cell TC1 may be an inverted T-shaped pattern, in a plan view. On the second PMOSFET region PR2, the first active pattern AP1 on the second tap cell TC2 may be a T-shaped pattern, in a plan view.

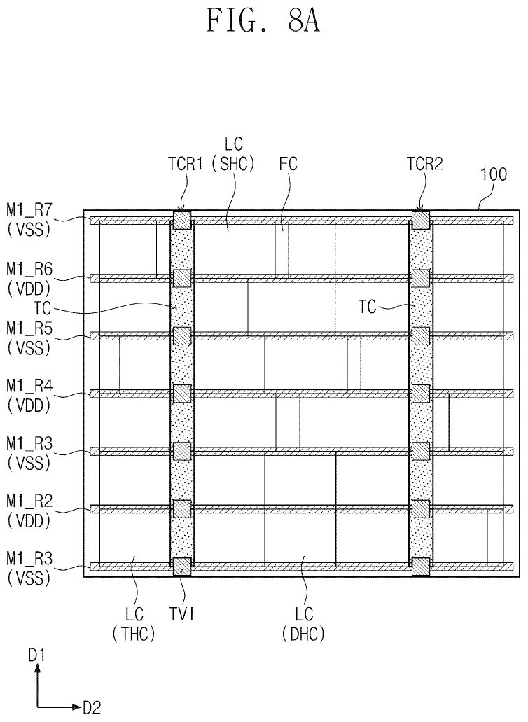

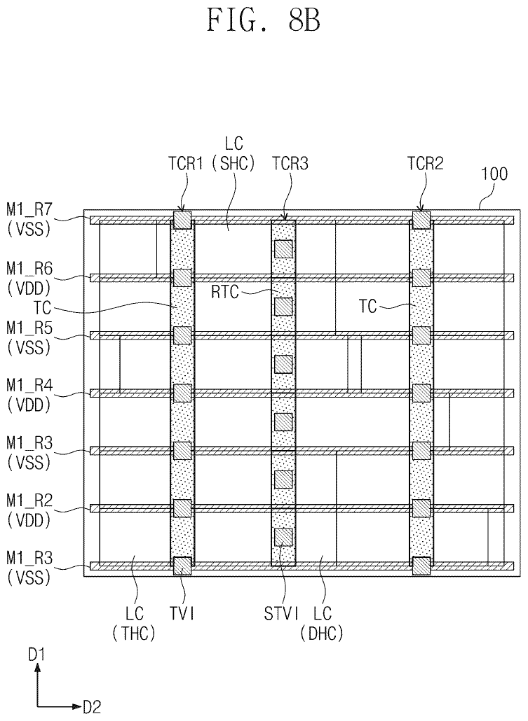

Each of FIGS. 8A and 8B is a plan view illustrating an arrangement of tap cells and logic cells in a semiconductor device according to an embodiment of the inventive concept.

Referring to FIG. 8A, first to seventh power lines M1_R1 to M1_R7 may be disposed on the substrate 100 and may be arranged in the first direction D1. A first tap cell track TCR1 and a second tap cell track TCR2 may be disposed on the substrate 100. Each of the first and second tap cell tracks TCR1 and TCR2 may be extended in the first direction D1. The first and second tap cell tracks TCR1 and TCR2 may be arranged at a specific pitch in the second direction D2.

On each of the first and second tap cell tracks TCR1 and TCR2, tap cells TC may be disposed in the first direction D1. For example, each of the tap cells TC in the present embodiment may be the tap cell TC1 or TC2 of FIG. 4.

The penetration via patterns TVI may be disposed on each of the first and second tap cell tracks TCR1 and TCR2 and may be arranged in the first direction D1. The penetration via patterns TVI may be coupled to the first to seventh power lines M1_R1 to M1_R7, respectively. The penetration via patterns TVI may be used to apply a voltage from the power delivery network layer PDN to the first to seventh power lines M1_R1 to M1_R7.

Logic cells LC and filler cells FC may be disposed on the substrate 100. The logic cells LC may be disposed on a remaining region, in which the tap cells TC are not disposed. The logic cells LC may be disposed on the substrate 100, based on the designed circuit. As an example, the logic cells LC may include at least one single height cell SHC, at least one double height cell DHC, and at least one triple height cell THC. The filler cell FC may fill an empty space between the logic cells LC, which are adjacent to each other. The filler cell FC may be a dummy cell.

Referring to FIG. 8B, a third tap cell track TCR3 may be disposed between the first and second tap cell tracks TCR1 and TCR2. Routing tap cells RTC may be disposed in the first direction D1, in the third tap cell track TCR3. Each of the routing tap cells RTC may include a signal penetration via pattern STVI. The signal penetration via pattern STVI may have substantially the same shape as the penetration via pattern TVI described above. In an embodiment, the signal penetration via pattern STVI may be disposed between the PMOSFET region and the NMOSFET region. The signal penetration via pattern STVI may be electrically connected to the power delivery network layer PDN.

The signal penetration via pattern STVI may be electrically connected to the logic cells LC adjacent to the third tap cell track TCR3. For example, a signal may be transmitted from the logic cell LC to the routing tap cell RTC through the first interconnection line M1_I in the first metal layer M1. The signal, which is transmitted to the routing tap cell RTC, may be connected to another logic cell LC through the power delivery network layer PDN. For example, the power delivery network layer PDN may be configured to provide a voltage to at least one of the power lines M1_R1 to M1_R7 as well as to serve as a routing structure for signal transmission.

Owing to the routing tap cell RTC in the present embodiment, the signal transmission in the semiconductor device may be achieved not only through a BEOL layer (e.g., the first and second metal layers M1 and M2), but also through the power delivery network layer PDN below the substrate 100. Accordingly, it may be possible to reduce complexity in the interconnection structure of the BEOL layer and to increase an integration density of the semiconductor device. Additionally, an electric resistance of the signal transmission path may be reduced, leading to an improvement in the electrical characteristics of the semiconductor device.

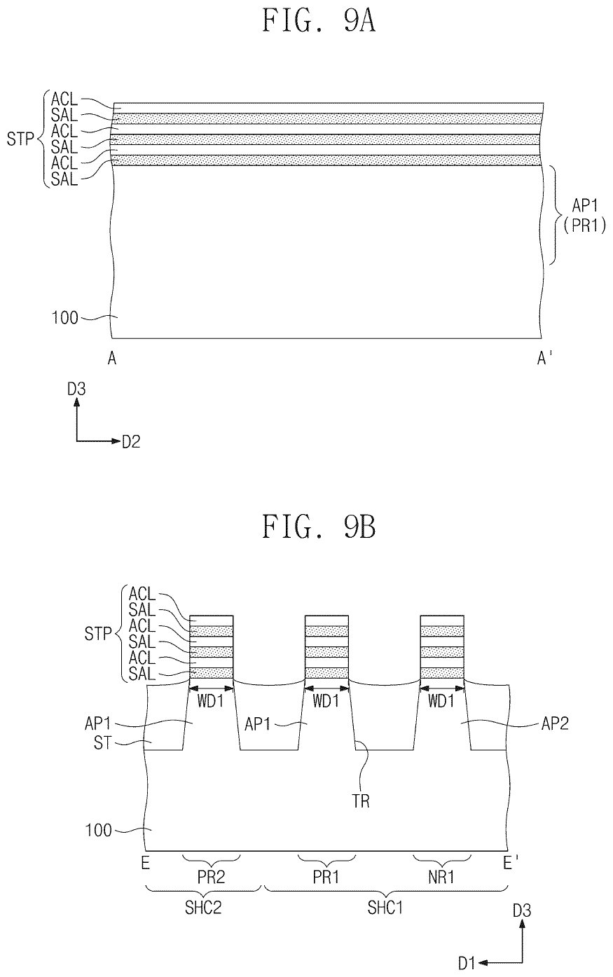

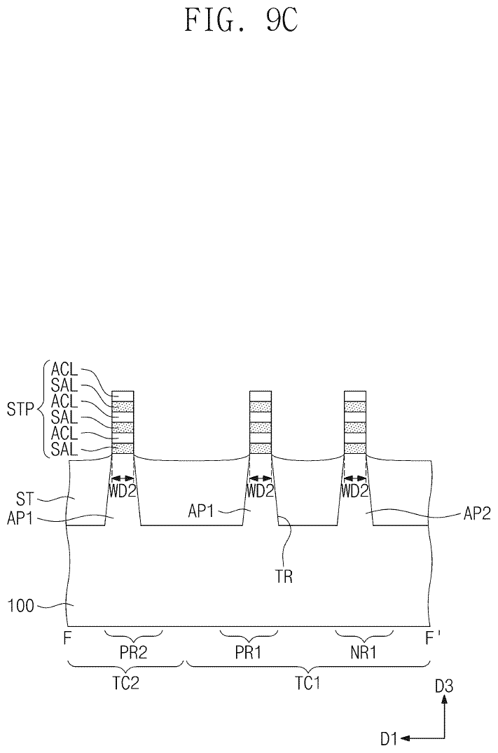

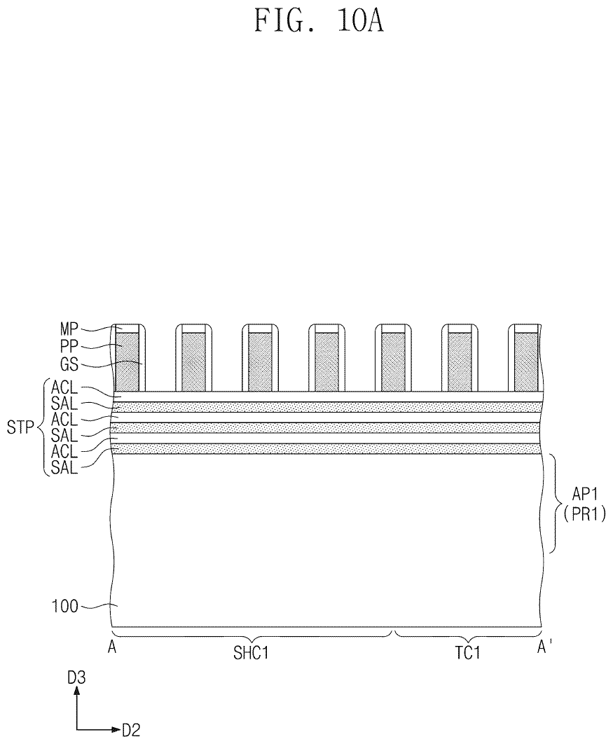

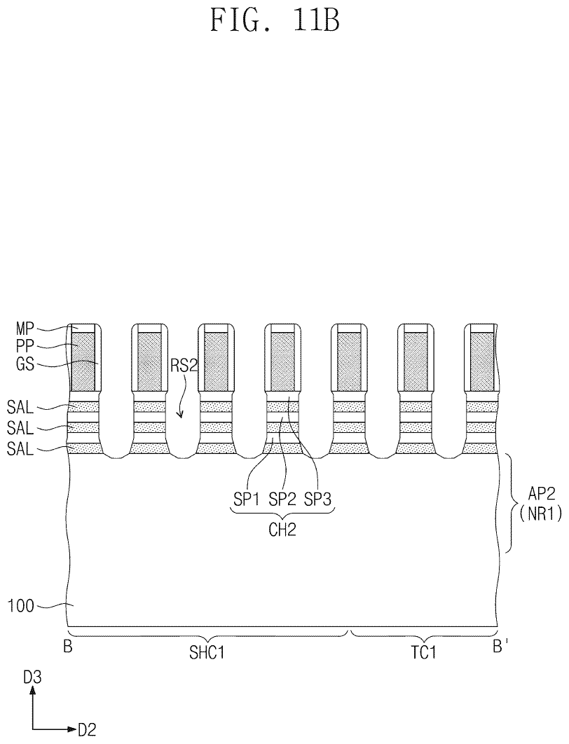

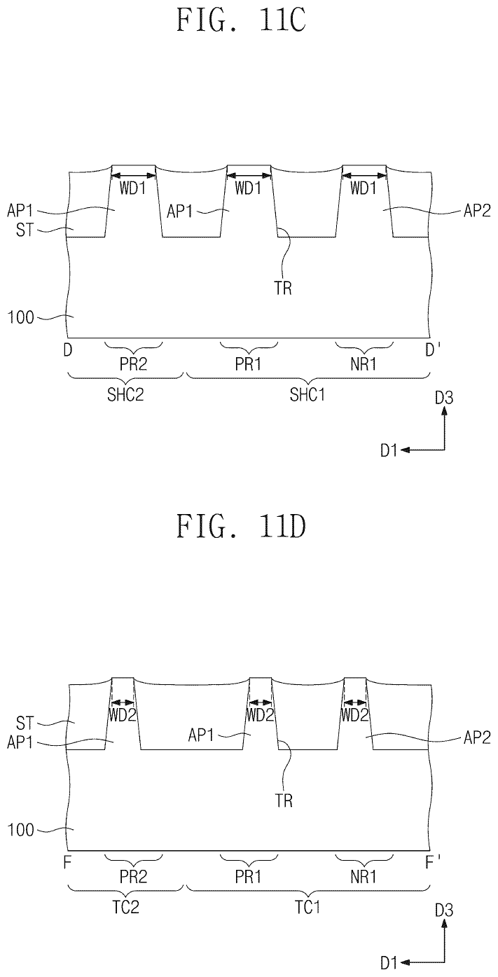

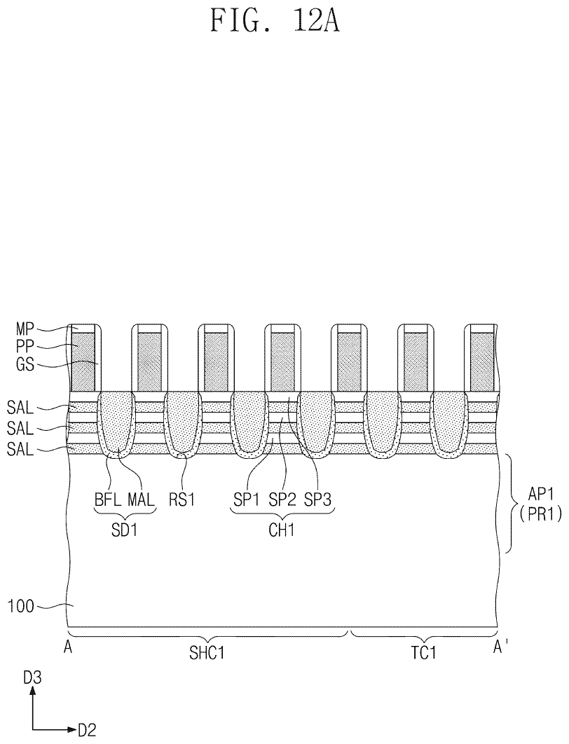

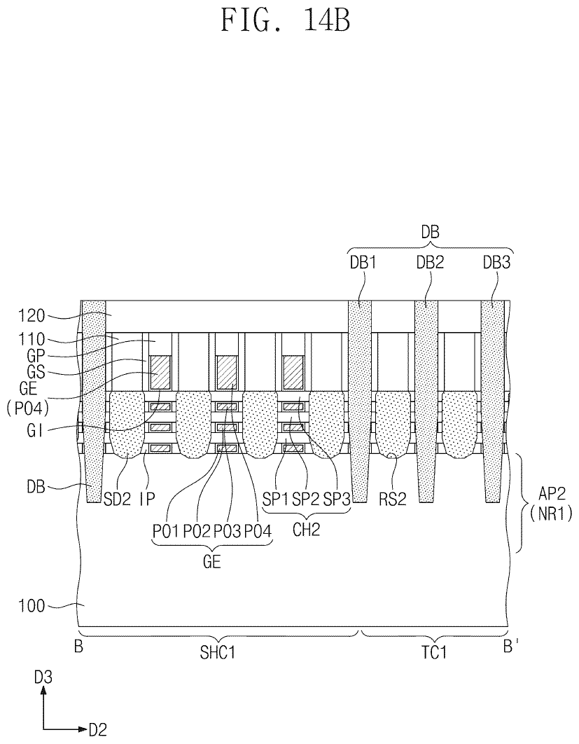

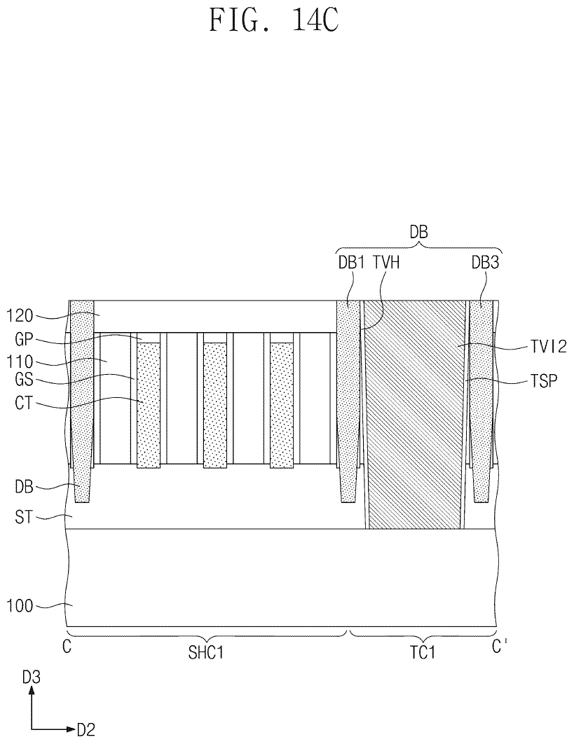

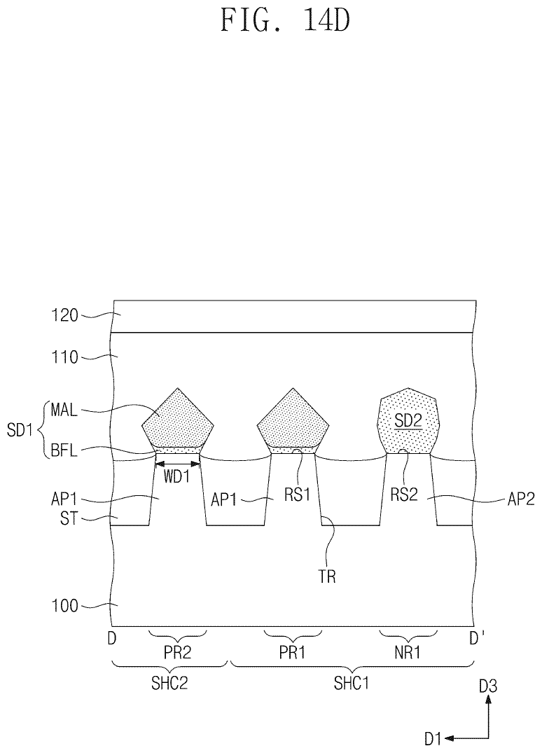

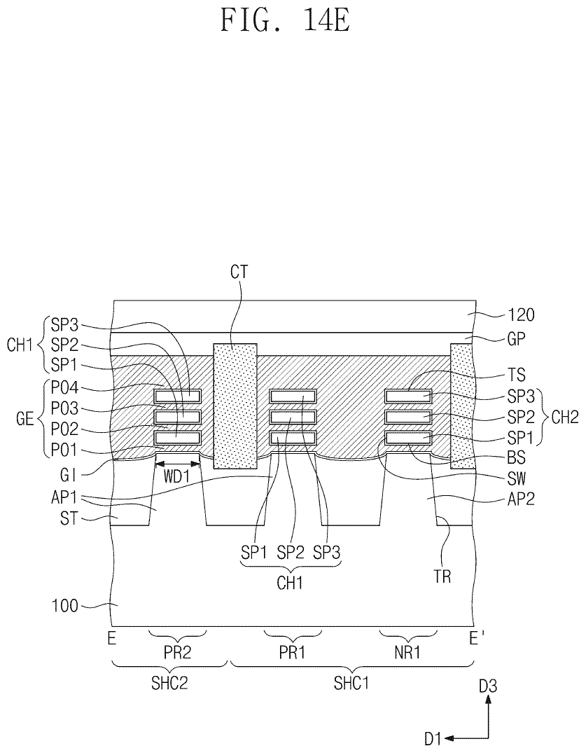

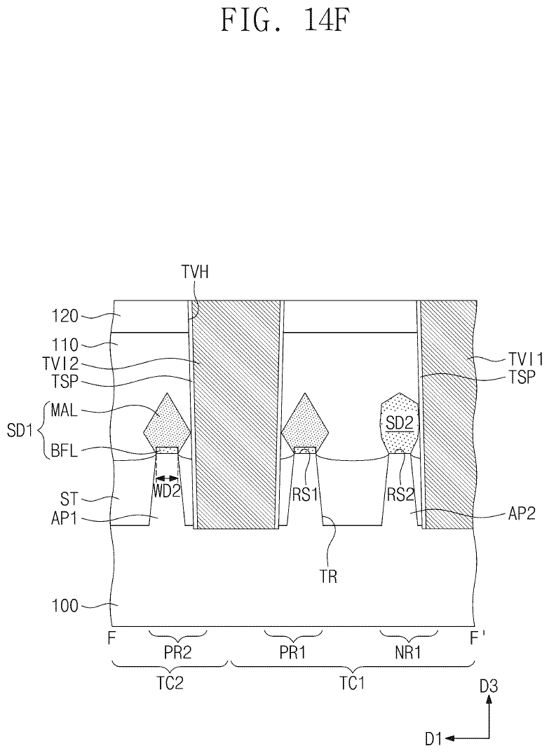

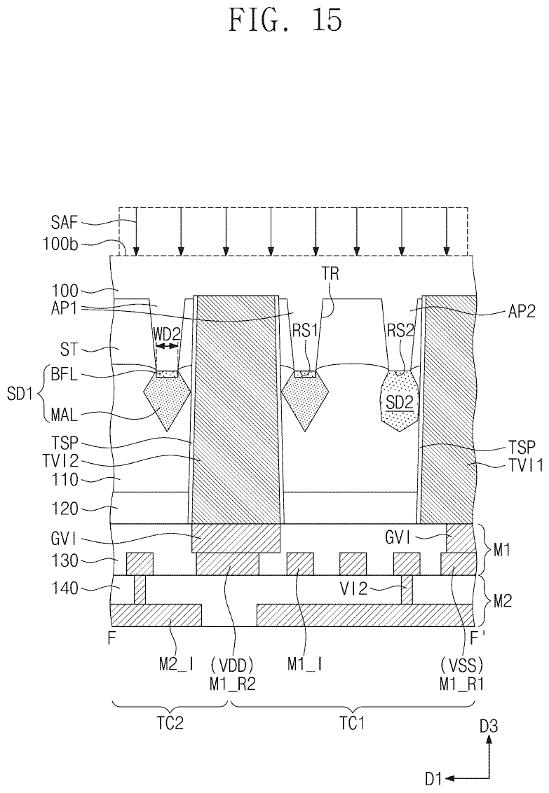

FIGS. 9A to 16 are cross-sectional views illustrating a method of fabricating a semiconductor device, according to an embodiment of the inventive concept. For example, FIGS. 9A, 10A, 11A, 12A, 13A, and 14A are cross-sectional views taken along a line A-A′ of FIG. 4. FIGS. 11B, 12B, 13B, and 14B are cross-sectional views taken along a line B-B′ of FIG. 4. FIG. 14C is a cross-sectional view taken along a line C-C′ of FIG. 4. FIGS. 11C, 12C, and 14D are cross-sectional views taken along a line D-D′ of FIG. 4. FIGS. 9B, 10B, 13C, and 14E are cross-sectional views taken along a line E-E′ of FIG. 4. FIGS. 9C, 11D, 12D, 14F, 15, and 16 are cross-sectional views taken along a line F-F′ of FIG. 4.

Referring to FIGS. 9A and 9C, the substrate 100 including the first and second PMOSFET regions PR1 and PR2 and the first and second NMOSFET regions NR1 and NR2 may be provided. First and second semiconductor layers ACL and SAL, which are alternately stacked on the substrate 100, may be formed. Each of the first and second semiconductor layers ACL and SAL may be formed of or may otherwise include silicon (Si), germanium (Ge), and/or silicon-germanium (SiGe), but the first and second semiconductor layers ACL and SAL may be formed of different materials from each other.

The second semiconductor layer SAL may be formed of or may otherwise include a material that is chosen to have an etch selectivity with respect to the first semiconductor layer ACL. For example, the first semiconductor layers ACL may be formed of or may otherwise include silicon (Si), and the second semiconductor layers SAL may be formed of or may otherwise include silicon-germanium (SiGe). A germanium concentration of each of the second semiconductor layers SAL may range from 10 at % to 30 at %.

Mask patterns may be respectively formed on the first and second PMOSFET regions PR1 and PR2 and the first and second NMOSFET regions NR1 and NR2 of the substrate 100. The mask pattern may be a line- or bar-shaped pattern that is extended in the second direction D2. For example, the mask pattern may be a bar-shaped pattern whose width is partially reduced.

A patterning process using the mask patterns as an etch mask may be performed to form the trench TR defining the first and second active patterns AP1 and AP2. The first active pattern AP1 may be formed on each of the first and second PMOSFET regions PR1 and PR2. The second active pattern AP2 may be formed on each of the first and second NMOSFET regions NR1 and NR2. In a plan view, the first and second active patterns AP1 and AP2 may be line-shaped patterns, which are extended in the second direction D2 and may run parallel to each other.

For example, the first or second active pattern AP1 or AP2 on the first or second single height cell SHC1 or SHC2 may have the first width WD1 in the first direction D1. The first or second active pattern AP1 or AP2 on the first or second tap cell TC1 or TC2 may have the second width WD2 in the first direction D1. In an embodiment, the first width WD1 may be larger than the second width WD2. In an embodiment, the first width WD1 may be substantially equal to the second width WD2. The first width WD1 may be 1.2 to 2.5 (in particular, 1.2 to 1.75) times the second width WD2. The difference between the first and second widths WD1 and WD2 may range from 0 nm to 15 nm.

A stacking pattern STP may be formed on each of the first and second active patterns AP1 and AP2. The stacking pattern STP may include the first semiconductor layers ACL and the second semiconductor layers SAL, which are alternately stacked. The stacking pattern STP may be formed along with the first and second active patterns AP1 and AP2, during the patterning process. The stacking pattern STP may also be formed on the first and second tap cells TC1 and TC2. In a plan view, the stacking pattern STP may be a bar- or line-shaped pattern whose width is partially reduced.

The device isolation layer ST may fill the trench TR. For example, an insulating layer may be formed on the substrate 100 and may cover the first and second active patterns AP1 and AP2 and the stacking patterns STP. The device isolation layer ST may be formed by recessing the insulating layer until the stacking patterns STP are exposed.

The device isolation layer ST may be formed of or may otherwise include at least one insulating material (e.g., silicon oxide). The stacking patterns STP may be disposed above the device isolation layer ST and may be exposed to the outside of the device isolation layer ST. For example, the stacking patterns STP may protrude vertically above the device isolation layer ST.

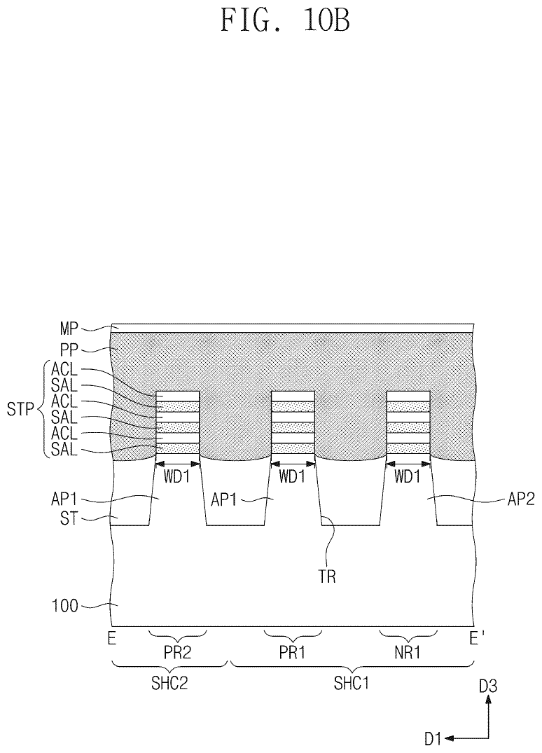

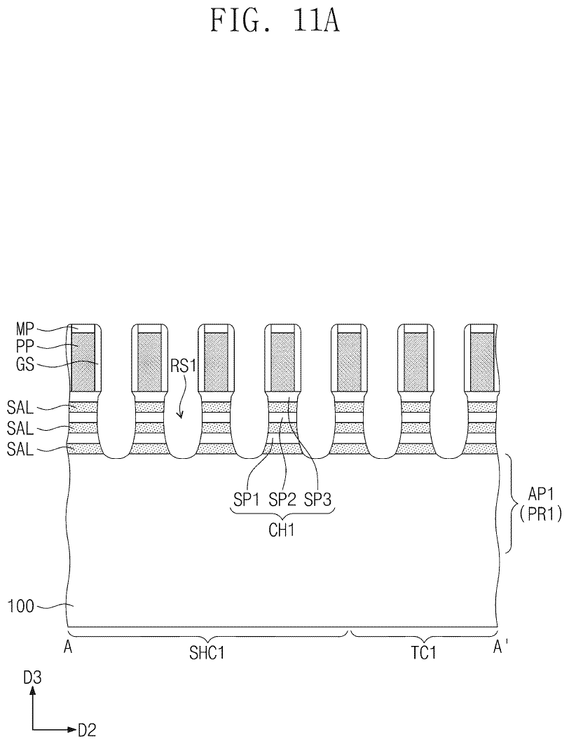

Referring to FIGS. 10A and 10B, sacrificial patterns PP may be formed on the substrate 100 and may cross the stacking patterns STP. Each of the sacrificial patterns PP may be a line- or bar-shaped pattern that is extended in the first direction D1. The sacrificial patterns PP may be arranged at a first pitch in the second direction D2.

For example, the formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may be formed of or may otherwise include polysilicon.

A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. The gate spacer layer may be formed of or may otherwise include SiCN, SiCON, and/or SiN. In an embodiment, the gate spacer layer may be a multi-layered structure including at least two of SiCN, SiCON, or SiN.

Referring to FIGS. 11A to 11D, the first recesses RS1 may be formed in the stacking pattern STP on the first active pattern AP1. The second recesses RS2 may be formed in the stacking pattern STP on the second active pattern AP2. During the formation of the first and second recesses RS1 and RS2, the device isolation layer ST may also be recessed at both sides of each of the first and second active patterns AP1 and AP2.

For example, the first recesses RS1 may be formed by etching the stacking pattern STP on the first active pattern AP1 using the hard mask patterns MP and the gate spacers GS as an etch mask. The first recess RS1 may be formed between a pair of the sacrificial patterns PP. The second recesses RS2 in the stacking pattern STP on the second active pattern AP2 may be formed by the same method as that for the first recesses RS1.

The first to third semiconductor patterns SP1, SP2, and SP3, which are sequentially stacked between adjacent ones of the first recesses RS1, may be formed from the first semiconductor layers ACL, respectively. The first to third semiconductor patterns SP1, SP2, and SP3, which are sequentially stacked between adjacent ones of the second recesses RS2, may be formed from the first semiconductor layers ACL, respectively. The first to third semiconductor patterns SP1, SP2, and SP3 between adjacent ones of the first recesses RS1 may constitute the first channel pattern CH1. The first to third semiconductor patterns SP1, SP2, and SP3 between the adjacent ones of the second recesses RS2 may constitute the second channel pattern CH2.

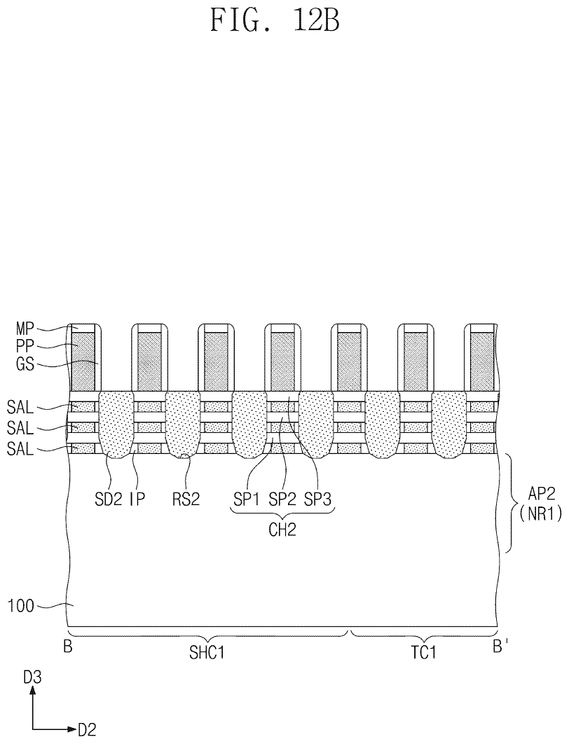

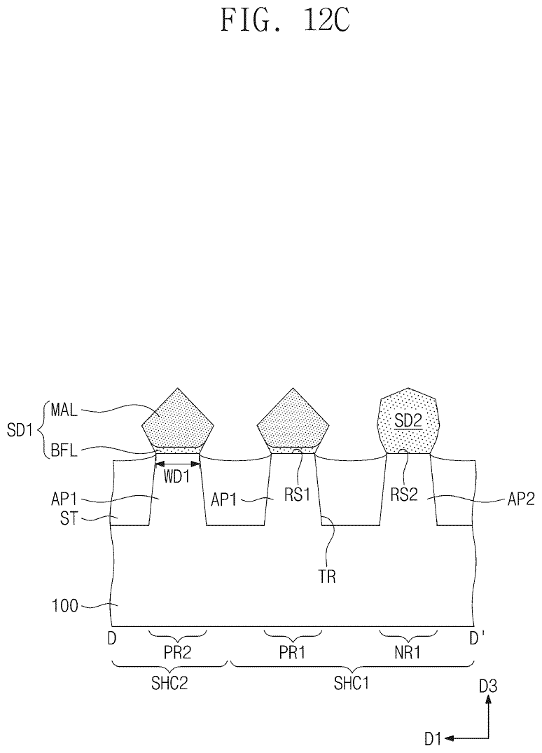

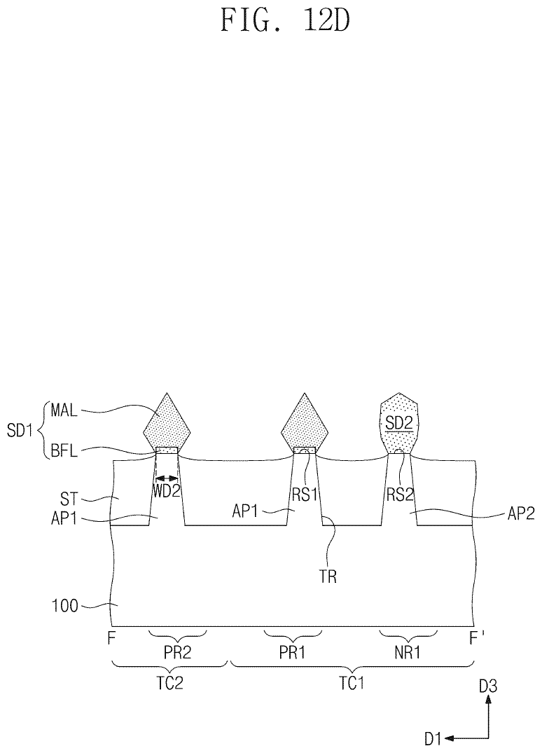

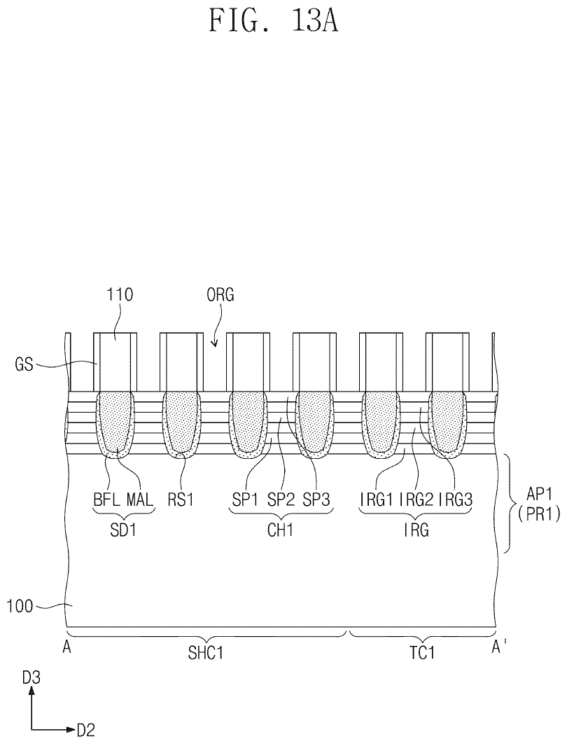

Referring to FIGS. 12A to 12D, the first source/drain patterns SD1 may be formed in the first recesses RS1, respectively. For example, the buffer layer BFL may be formed by a first SEG process using an inner surface of the first recess RS1 as a seed layer. The buffer layer BFL may be grown using the first to third semiconductor patterns SP1, SP2, and SP3 and the substrate 100, which are exposed through the first recess RS1, as a seed layer. As an example, the first SEG process may include a chemical vapor deposition (CVD) process or a molecular beam epitaxy (MBE) process.

The buffer layer BFL may contain a semiconductor material (e.g., SiGe) whose lattice constant is larger than that of a semiconductor material of the substrate 100. The buffer layer BFL may contain a relatively low concentration of germanium (Ge). In an embodiment, the buffer layer BFL may contain only silicon (Si), without germanium (Ge). A germanium concentration of the buffer layer BFL may range from 0 at % to 10 at %.

A second SEG process may be performed on the buffer layer BFL to form the main layer MAL. The main layer MAL may completely or nearly completely fill the first recess RS1. The main layer MAL may contain a relatively high concentration of germanium. As an example, a germanium concentration of the main layer MAL may range from 30 at % to 70 at %.

In an embodiment, a third SEG process may be performed on the main layer MAL to form a capping layer. The capping layer may be formed of or may otherwise include silicon (Si). A silicon concentration of the capping layer may range from 98 at % to 100 at %.

The first source/drain pattern SD1 may be doped in-situ with p-type impurities (e.g., boron, gallium, or indium) during the formation of the buffer and main layers BFL and MAL. Alternatively, impurities may be injected into the first source/drain pattern SD1, after the formation of the first source/drain pattern SD1.

The second source/drain patterns SD2 may be formed in the second recesses RS2, respectively. For example, the second source/drain pattern SD2 may be formed by a SEG process, in which an inner surface of the second recess RS2 is used as a seed layer. In an embodiment, the second source/drain pattern SD2 may be formed of or may otherwise include the same semiconductor material (e.g., Si) as the substrate 100.

During the formation of the second source/drain pattern SD2, the second source/drain pattern SD2 may be doped in-situ with n-type impurities (e.g., phosphorus, arsenic, or antimony). Alternatively, impurities may be injected into the second source/drain pattern SD2, after the formation of the second source/drain pattern SD2.

In an embodiment, before the formation of the second source/drain pattern SD2, the inner spacer IP may be formed by replacing a portion of the second semiconductor layer SAL, which is exposed by the second recess RS2, with an insulating material. As a result, the inner spacers IP may be respectively formed between the second source/drain pattern SD2 and the second semiconductor layers SAL.

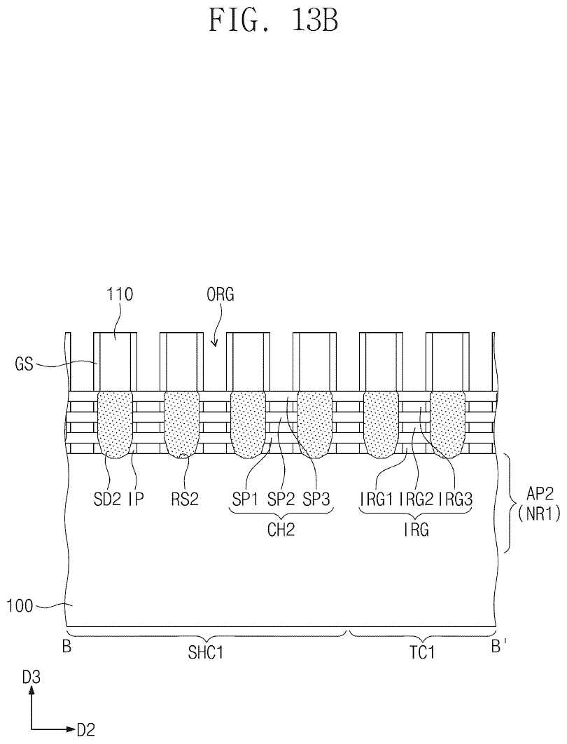

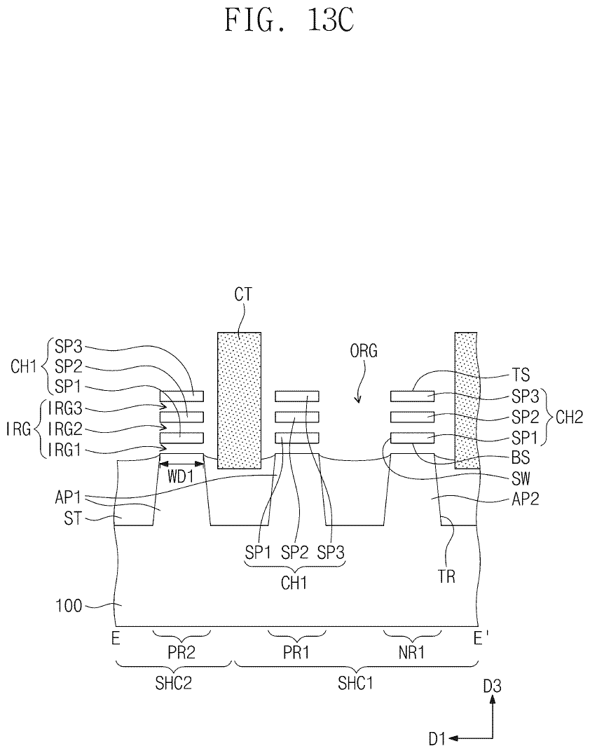

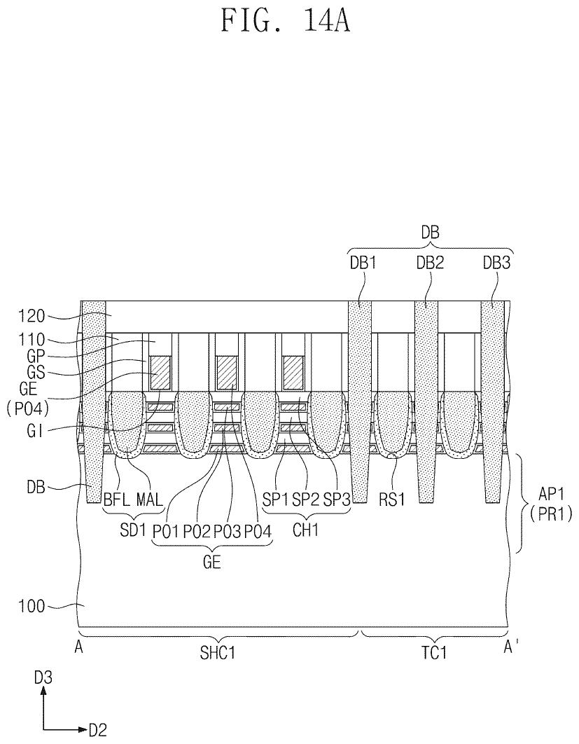

Referring to FIGS. 13A to 13C, the first interlayer insulating layer 110 may cover the first and second source/drain patterns SD1 and SD2, the hard mask patterns MP, and the gate spacers GS. In an embodiment, the first interlayer insulating layer 110 may include a silicon oxide layer.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. All of the hard mask patterns MP may be removed during the planarization process. As a result, the first interlayer insulating layer 110 may have a top surface that is coplanar with the top surfaces of the sacrificial patterns PP and the top surfaces of the gate spacers GS.

A photolithography process may be performed to selectively open a region of the sacrificial pattern PP. For example, a region of the sacrificial pattern PP, which is located on a boundary between the first and second single height cells SHC1 and SHC2, may be selectively opened. The opened region of the sacrificial pattern PP may be selectively etched and removed. The gate cutting pattern CT may be formed by filling a space, which is formed by removing the sacrificial pattern PP, with an insulating material (e.g., see FIG. 13C).

In an embodiment, the exposed sacrificial patterns PP may be selectively removed. As a result of the removal of the sacrificial patterns PP, an outer region ORG may expose the first and second channel patterns CH1 and CH2 (e.g., see FIG. 13C). The removal of the sacrificial patterns PP may include a wet etching process which is performed using an etching solution capable of selectively etching polysilicon.

The second semiconductor layers SAL, which are exposed through the outer region ORG, may be selectively removed to form inner regions IRG (e.g., see FIG. 13C). For example, an etching process of selectively etching the second semiconductor layers SAL may be performed to leave the first to third semiconductor patterns SP1, SP2, and SP3 and to remove only the second semiconductor layers SAL. An etch recipe for the etching process may be chosen to etch a layer (e.g., a silicon germanium layer), which is formed to have a relatively high germanium concentration, at a high etch rate. For example, the etching process may be chosen to have a high etch rate to a silicon germanium layer whose germanium concentration is higher than 10 at %.

During the etching process, the second semiconductor layers SAL may be completely removed from the first and second PMOSFET regions PR1 and PR2 and the first and second NMOSFET regions NR1 and NR2. The etching process may be a wet etching process. An etchant material, which is used in the etching process, may be chosen to quickly remove the second semiconductor layer SAL having a relatively high germanium concentration. The first source/drain patterns SD1 on the first and second PMOSFET regions PR1 and PR2 may be protected from the etching process by the buffer layer BFL having a relatively low germanium concentration.

Referring back to FIG. 13C, as a result of the selective removal of the second semiconductor layers SAL, the stacked first to third semiconductor patterns SP1, SP2, and SP3 may be left on each of the first and second active patterns AP1 and AP2. Empty regions, which are formed by removing the second semiconductor layers SAL, may form first to third inner regions IRG1, IRG2, and IRG3, respectively.

For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring to FIGS. 14A to 14F, the gate insulating layer GI may be conformally formed on the exposed first to third semiconductor patterns SP1, SP2, and SP3. The gate electrode GE may be formed on the gate insulating layer GI. The gate electrode GE may include the first to third inner electrodes PO1, PO2, and PO3, which are formed in the first to third inner regions IRG1, IRG2, and IRG3, and the outer electrode PO4, which is formed in the outer region ORG.

The gate electrode GE may be vertically recessed to have a reduced height. Upper portions of the gate cutting patterns CT may be slightly recessed, during the recessing of the gate electrode GE. The gate capping pattern GP may be formed on the recessed gate electrode GE. The gate capping patterns GP may be formed on the slightly-recessed portions of the gate cutting patterns CT.

The second interlayer insulating layer 120 may be formed on the first interlayer insulating layer 110. The second interlayer insulating layer 120 may include a silicon oxide layer. The division structures DB may be formed on a boundary between the cells. The division structures DB may be extended from the second interlayer insulating layer 120 into the active pattern AP1 or AP2 to penetrate the gate electrode GE. The division structures DB may include the first division structure DB1, the second division structure DB2, and the third division structure DB3. The division structures DB may be formed of or may otherwise include an insulating material (e.g., silicon oxide or silicon nitride).

Referring back to FIGS. 14C and 14F, penetration holes TVH may penetrate the first and second interlayer insulating layers 110 and 120 and to expose the substrate 100. For example, at least one penetration hole TVH may be disposed on a boundary region between the first and second tap cells TC1 and TC2. The penetration hole TVH may be formed between a pair of the first active patterns AP1. The penetration hole TVH may expose a bottom of the trench TR, which is located between the pair of the first active patterns AP1. As a distance to the substrate 100 decreases, a width of the penetration hole TVH may decrease.

An upper spacer TSP may be formed on an inner side surface of the penetration hole TVH. The upper spacer TSP may be formed of or may otherwise include at least one of silicon-based insulating materials. The first to third penetration via patterns TVI1 to TVI3 may be formed by filling the penetration holes TVH with a metallic material.

In the semiconductor device, according to an embodiment of the inventive concept, when tap cells are formed between logic cells, it may be possible to omit an additional process of partially removing an active region extended from logic cells. For example, the additional process of partially removing the active region may be a fin-cut process and may include removing a portion of the active region and forming an insulating material in the removed region. It may be possible to easily form a penetration via pattern of the tap cell between the active regions adjacent to a metal line and thereby to reduce a threshold voltage (V_{TH}) shift phenomenon in a transistor caused by the insulating material. For example, since an additional process to remove a portion of the active region is not performed, it may be possible to reduce a local layout effect and to improve electrical characteristics of the semiconductor device.

In the semiconductor device, according to an embodiment of the inventive concept, since the process of removing a portion of the active region is not performed, it may be possible to prevent a leaning phenomenon from occurring in the gate electrode adjacent to the tap cell. Since the leaning phenomenon is prevented, it may be possible to prevent a recess failure in a source/drain region and to prevent a pattern failure in a subsequent step, and as a result, the reliability of the semiconductor device may be increased.

Thereafter, the active contacts AC may penetrate the second interlayer insulating layer 120 and the first interlayer insulating layer 110 and may be electrically connected to the first and second source/drain patterns SD1 and SD2, as previously described with reference to FIG. 4 and FIGS. 5A to 5F. The gate contact GC may penetrate the second interlayer insulating layer 120 and the gate capping pattern GP and may be electrically connected to the gate electrode GE. The third interlayer insulating layer 130 may be formed on the active contacts AC and the gate contacts GC. The first metal layer M1 may be formed in the third interlayer insulating layer 130. The first metal layer M1 may include the first to third power lines M1_R1, M1_R2, and M1_R3, which are electrically connected to the first to third penetration via patterns TVI1-TVI3, respectively. The fourth interlayer insulating layer 140 may be formed on the third interlayer insulating layer 130. The second metal layer M2 may be formed in the fourth interlayer insulating layer 140.

Referring to FIG. 15, after a BEOL process, the substrate 100 may be inverted such that the bottom surface 100b of the substrate 100 is exposed to the outside. A planarization process SAF may be performed on the bottom surface 100b of the substrate 100 to reduce the thickness of the substrate 100.

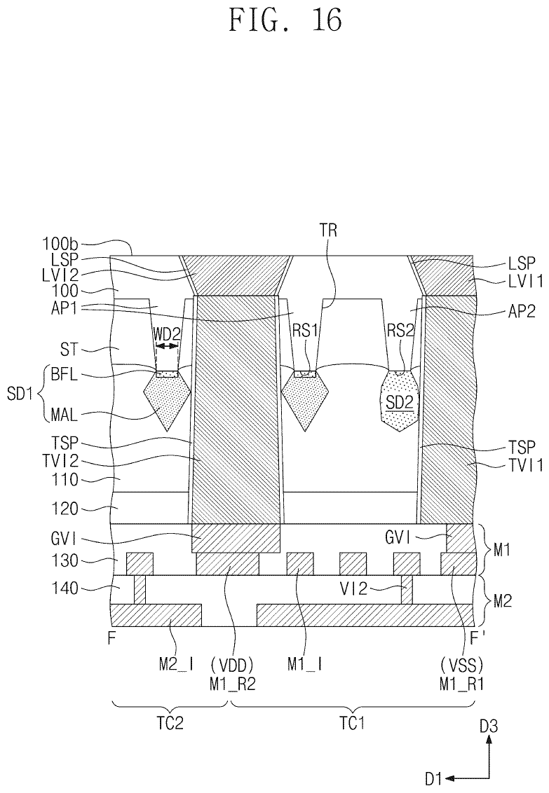

Referring to FIG. 16, the lower via patterns LVI1 and LVI2 may be formed by performing a patterning process on the bottom surface 100b of the substrate 100. The lower via patterns LVI1 and LVI2 may be vertically aligned to the first to third penetration via patterns TVI1, TVI2, and TVI3, respectively. The lower via patterns LVI1 and LVI2 may be directly connected to the first to third penetration via patterns TVI1, TVI2, and TVI3, respectively. Thereafter, the power delivery network layer PDN may be formed on the bottom surface 100b of the substrate 100. The power delivery network layer PDN may apply a source voltage or a drain voltage to the first to third power lines M1_R1, M1_R2, and M1_R3.

In a three-dimensional field effect transistor, according to an embodiment of the inventive concept, an active region on a power tap cell may have a width that is smaller than a width of an active region on a logic cell, and in this case, it may be possible to omit a process of removing the active region in a subsequent step. Thus, it may be possible to easily form a penetration via pattern in the power tap cell and thereby to reduce a local layout effect. For example, it may be possible to prevent a threshold voltage (V_{TH}) shift phenomenon in a transistor of the logic cell and consequently to improve the electrical characteristics of the semiconductor device.

In a three-dimensional field effect transistor, according to an embodiment of the inventive concept, since a process of partially removing the active region can be omitted, it may be possible to prevent a leaning phenomenon from occurring in a gate electrode adjacent to the power tap cell. As a result, it may be possible to reduce a recess failure and a pattern failure in a source/drain region and consequently to increase the reliability characteristics of the semiconductor device.

While example embodiments of the inventive concept have been particularly shown and described, it will be understood by one of ordinary skill in the art that variations in form and detail may be made therein without departing from the spirit and scope of the present disclosure.

What is claimed is:

1. A semiconductor device, comprising:
a plurality of power lines disposed on a substrate, each of the power lines are arranged in a first direction and extended in a second direction;
a first single height cell and a second single height cell arranged in the first direction on the substrate;
a first tap cell and a second tap cell arranged in the first direction on the substrate, the first tap cell and the first single height cell being arranged in the second direction, the second tap cell and the second single height cell being arranged in the second direction;
a power delivery network layer disposed below the substrate; and
a first active pattern and a second active pattern disposed between the power lines and spaced apart from each other in the first direction,
wherein the first and second active patterns are extended in the second direction and cross the first single height cell and the first tap cell, and
wherein a first width of the first active pattern on the first single height cell is larger than or equal to a second width of the first active pattern on the first tap cell, measured in the first direction.

2. The semiconductor device of claim 1, wherein the first width is 1.5 to 2.5 times the second width.

3. The semiconductor device of claim 1, wherein a difference between the first and second widths ranges from 0 nm to 15 nm.

4. The semiconductor device of claim 1, wherein the first active pattern on the first tap cell is a U-shaped pattern, in a plan view.

5. The semiconductor device of claim 1, wherein the first active pattern on the first tap cell is an inverted U-shaped pattern, in a plan view.

6. The semiconductor device of claim 1, wherein the first and second tap cells comprise a plurality of penetration via patterns, that are electrically connected to the power lines, respectively,
wherein the power delivery network layer is configured to apply at least one voltage to the power lines through the penetration via pattern,
wherein the first and second tap cells comprise a plurality of division structures arranged in the second direction, and
wherein a width of each of the penetration via patterns in the second direction is two times a pitch between the division structures.

7. The semiconductor device of claim 6, wherein the first and second single height cells comprise a plurality of gate electrodes arranged in the second direction, and
wherein a width of each of the first and second tap cells in the second direction is two times a pitch between the gate electrodes.

8. The semiconductor device of claim 7, wherein the pitch between the division structures is substantially equal to the pitch between the gate electrodes.

9. The semiconductor device of claim 6, wherein the division structures comprise a first division structure, a second division structure, and a third division structure, which are sequentially spaced apart from each other in the second direction, and
wherein the first division structure and the third division structure are disposed on opposite borders of each of the first and second tap cells.

10. The semiconductor device of claim 9, wherein a distance between the first and second division structures is substantially equal to a distance between the second and third division structures.

11. A semiconductor device, comprising:
first active patterns disposed on a substrate, adjacent to each other;
first source/drain patterns respectively disposed on the first active patterns, adjacent to each other;
a first division structure, a second division structure, and a third division structure crossing the first active patterns, the first source/drain patterns being respectively interposed between the first and second division structures and between the second and third division structures;
a penetration via pattern disposed between the first source/drain patterns;
a first power line disposed on the penetration via pattern and electrically connected to the penetration via pattern;
a power delivery network layer disposed on a bottom surface of the substrate; and
a lower via pattern disposed between the power delivery network layer and the penetration via pattern,
wherein a bottom surface of the penetration via pattern is located at a level that is lower than that of a bottom surface of each of the first to third division structures.

12. The semiconductor device of claim 11, wherein the largest width of the lower via pattern in a first direction is larger than the largest width of the penetration via pattern in the first direction.

13. The semiconductor device of claim 11, further comprising a giant via pattern connecting the penetration via pattern to the first power line,
wherein the largest width of the giant via pattern in a first direction is smaller than or equal to the largest width of the penetration via pattern in the first direction.

14. The semiconductor device of claim 13, wherein the largest width of the giant via pattern in the first direction is substantially equal to the largest width of the penetration via pattern in the first direction.

15. The semiconductor device of claim 11, wherein a width of the penetration via pattern in a first direction decreases as a distance to a bottom surface of the substrate decreases.

16. A semiconductor device, comprising:
a first power line and a second power line disposed on a substrate, the first and second power lines being spaced apart from each other in a first direction and being extended in a second direction;
a single height cell and a tap cell disposed between the first and second power lines, the single height cell and the tap cell being adjacent to each other in the second direction;
a first active pattern and a second active pattern disposed on the single height cell and the tap cell, the first and second active patterns being spaced apart from each other in the first direction and being extended in the second direction;
a first channel pattern and a first source/drain pattern disposed on the first active pattern;
a second channel pattern and a second source/drain pattern disposed on the second active pattern, the second source/drain pattern having a conductivity type that is different from that the first source/drain pattern;
a gate electrode disposed on the first and second channel patterns;
a gate insulating layer interposed between the gate electrode and the first and second channel patterns;
a gate spacer disposed on a side surface of the gate electrode;
a gate capping pattern disposed on a top surface of the gate electrode;
an interlayer insulating layer covering the first and second source/drain patterns and the gate capping pattern;
an active contact penetrating the interlayer insulating layer and electrically connected to each of the first and second source/drain patterns;
a metal-semiconductor compound layer interposed between the active contact and each of the first and second source/drain patterns;
a gate contact penetrating the interlayer insulating layer and the gate capping pattern and electrically connected to the gate electrode;
a first division structure, a second division structure, and a third division structure arranged in the second direction, the first and third division structures being respectively disposed on opposite borders of the tap cell;
a first penetration via pattern and a second penetration via pattern disposed on the tap cell, the first and second penetration via patterns being electrically connected to the first and second power lines, respectively, and each of the first and second penetration via patterns being interposed between the first and third division structures;
a power delivery network layer disposed on a bottom surface of the substrate; and
a first lower via pattern and a second lower via pattern disposed between the power delivery network layer and the first and second penetration via patterns, respectively,
wherein the largest width of each of the first and second lower via patterns in the second direction is larger than the largest width of each of the first and second penetration via patterns in the second direction.

17. The semiconductor device of claim 16, wherein a first width of the first active pattern on the single height cell is smaller than or equal to a second width of the first active pattern on the tap cell, in the first direction.

18. The semiconductor device of claim 17, wherein the first active pattern on the tap cell is a T-shaped pattern or an inverted T-shaped pattern, in a plan view.

19. The semiconductor device of claim 16, wherein a first width of the first active pattern on the single height cell is larger than a second width of the first active pattern on the tap cell, when measured in the first direction.

20. The semiconductor device of claim 19, wherein the first active pattern on the tap cell is a U-shaped pattern or an inverted U-shaped pattern, in a plan view.
